(19) United States
(12) Patent Application Publication
(10) Pub. No.: US 2024/0414986 A1
(43) Pub. Date: Dec. 12, 2024

(54) DISPLAY DEVICE

(71) Applicant: Samsung Display Co., LTD., Yongin-si (KR)

(72) Inventors: SIKWANG KIM, Yongin-si (KR); JIN-SU BYUN, Yongin-si (KR); Giheon CHOI, Yongin-si (KR); PIL SOON HONG, Yongin-si (KR)

(21) Appl. No.: 18/626,124

(22) Filed: Apr. 3, 2024

(30) Foreign Application Priority Data
Jun. 7, 2023 (KR) 10-2023-0073019

(51) Int. Cl. H10K 59/80; H10K 59/40; H10K 102/00

(52) U.S. Cl. CPC H10K 59/879; H10K 59/40; H10K 59/872; H10K 59/873; H10K 59/8791; H10K 2102/351

(57) ABSTRACT

A display device includes: a display panel; an input sensing unit including a sensing insulation layer and a conductive layer, which overlaps the non-emissive region; a light control layer disposed on the input sensing unit; and a window disposed on the light control layer. The light control layer includes: a high refractive index pattern, which covers each of a plurality of emissive regions in a plan view and has a first refractive index; and a low refractive index layer, which covers the high refractive index pattern and the conductive layer, and has a second refractive index smaller than the first refractive index. A separation distance by which one side surface of the high refractive index pattern is spaced apart from one side surface of an emissive region closest to the one side surface of the high refractive index pattern among the emissive regions ranges from 6 μm to 9 μm.

This application claims priority to Korean Patent Application No. 10-2023-0073019, filed on Jun. 7, 2023, and all the benefits accruing therefrom under U.S.C. § 119, the content of which in its entirety is herein incorporated by reference.

### BACKGROUND

Embodiments of the present disclosure described herein relate to a display device and a manufacturing method thereof, and more particularly, relate to a display device including a high refractive index pattern and a low refractive index layer.

Various display devices used in multimedia devices, such as televisions, mobile phones, tablet computers, game machines, and the like, are being developed. The display devices may include various optical functional layers to provide color images of excellent quality to users.

Meanwhile, studies on thin display devices are being conducted to implement various forms of display devices such as a display device including a curved surface, a rollable display device, and a foldable display device. The thin display devices may be implemented by reducing the number of optical functional layers and including an optical functional layer having various functions.

### SUMMARY

Embodiments of the present disclosure provide a display device for improving light efficiency and increasing the luminance of a side surface of the display device.

According to an embodiment, a display device includes: a display panel including a plurality of emissive regions and a non-emissive region adjacent to the plurality of emissive regions; an input sensing unit, which is disposed on the display panel, includes a sensing insulation layer disposed on the display panel and a conductive layer disposed on the sensing insulation layer and overlaps the non-emissive region; a light control layer disposed on the input sensing unit; and a window, which is disposed on the light control layer and includes a front surface and a curved surface curved from the front surface. The light control layer includes: a high refractive index pattern, which is disposed on the sensing insulation layer and covers each of the plurality of emissive regions in a plan view and has a first refractive index; and a low refractive index layer, which covers the high refractive index pattern and the conductive layer, overlaps the non-emissive region and the emissive region, and has a second refractive index smaller than the first refractive index. A separation distance by which one side surface of the high refractive index pattern is spaced apart from one side surface of an emissive region closest to the one side surface of the high refractive index pattern among plurality of emissive regions ranges from 6 micrometers (μm) to 9 μm in the plan view.

The display panel may include: a base layer; a light emitting element, which is disposed on the base layer and overlaps the emissive region; and a thin film encapsulation layer, which is disposed on the light emitting element and seals the light emitting element, and the thin film encapsulation layer may have a thickness of 10 μm to 11 μm.

The high refractive index pattern may have a thickness of 2 μm to 5 μm.

A side angle formed by a side surface of the high refractive index pattern with respect to an upper surface of the sensing insulation layer may range from 60 degrees to 90 degrees.

The side angle may range from 60 degrees to 70 degrees, and a difference between the first refractive index and the second refractive index may range from 0.25 to 0.35.

The separation distance may increase as the side angle decreases.

A difference between the first refractive index and the second refractive index may be 0.25 or less.

The first refractive index may range from 1.5 to 1.8.

The second refractive index may range from 1.3 to 1.5.

The input sensing unit may include: a first sensing insulation layer disposed on the display panel; a first conductive layer, which is disposed on the first sensing insulation layer and overlaps the non-emissive region; a second sensing insulation layer, which is disposed on the first sensing insulation layer and covers at least part of the first conductive layer; and a second conductive layer, which is disposed on the second sensing insulation layer and overlaps the non-emissive region, and the low refractive index layer may cover the second conductive layer.

The separation distance may increase as a thickness of the high refractive index pattern increases.

The separation distance may increase as a difference between the first refractive index and the second refractive index increases.

The plurality of emissive regions may include: a first emissive region, which emits red light and a second emissive region, which emits green light. The high refractive index pattern may be provided in plurality. The plurality of high refractive index patterns may include: a first high refractive index pattern, which covers the first emissive region in the plan view; and a second high refractive index pattern, which covers the second emissive region in the plan view. One side surface of the first high refractive index pattern may be spaced apart from one side surface of the first emissive region closest to the one side surface of the first high refractive index pattern by a first separation distance in the plan view. One side surface of the second high refractive index pattern may be spaced apart from one side surface of the second emissive region closest to the one side surface of the second high refractive index pattern by a second separation distance in the plan view. The second separation distance may be different from the first separation distance.

The second separation distance may be greater than the first separation distance.

The display device may further include a polarization unit directly disposed on the low refractive index layer.

The high refractive index pattern may have a thickness of 10 μm or more.

According to an embodiment, a display device includes: a display panel including a plurality of emissive regions and a non-emissive region adjacent to the plurality of emissive regions; an input sensing unit, which is disposed on the display panel, includes a sensing insulation layer disposed on the display panel and a conductive layer disposed on the sensing insulation layer. and overlaps the non-emissive region; a light control layer disposed on the input sensing unit; and a window, which is disposed on the light control layer and includes a front surface and a curved surface curved from the front surface. The light control layer includes: a low refractive index pattern, which is disposed on the sensing insulation layer, covers the conductive layer, overlaps the non-emissive region, and has a first refractive index; and a high refractive index layer, which covers the low refractive index pattern, overlaps the non-emissive region and the emissive region, and has a second refractive index greater than the first refractive index. A separation distance by which one side surface of the low refractive index pattern is spaced apart from one side surface of the emissive region closest to the one side surface of the low refractive index pattern ranges from 6 μm to 9 μm in the plan view.

The display panel may include a base layer; a light emitting element, which is disposed on the base layer and overlaps the emissive region; and a thin film encapsulation layer, which is disposed on the light emitting element and seals the light emitting element, and the thin film encapsulation layer may have a thickness of 10 μm to 11 μm.

A side angle formed by a side surface of the low refractive index pattern with respect to an upper surface of the sensing insulation layer may range from 90 degrees to 120 degrees.

The first refractive index may range from 1.3 to 1.5.

The second refractive index may range from 1.5 to 1.8.

### BRIEF DESCRIPTION OF THE FIGURES

The above and other aspects and features of the present disclosure will become apparent by describing in detail embodiments thereof with reference to the accompanying drawings.

FIG. 1 is a perspective view of a display device according to an embodiment of the present disclosure.

FIG. 2 is an exploded perspective view of the display device according to an embodiment of the present disclosure.

FIG. 3 is a sectional view taken along line I-I′ of FIG. 1 according to an embodiment of the present disclosure.

FIG. 4 is a sectional view of the display device according to an embodiment of the present disclosure.

FIG. 5A is a plan view of a display panel according to an embodiment of the present disclosure.

FIG. 5B is a sectional view of the display panel according to an embodiment of the present disclosure.

FIG. 6 is a plan view of an input sensing unit according to an embodiment of the present disclosure.

FIG. 7 is an enlarged plan view of an active region according to an embodiment of the present disclosure.

FIG. 8 is a sectional view of the display device taken along line II-II′ of FIG. 7 according to an embodiment of the present disclosure.

FIG. 9 is an enlarged sectional view illustrating region AA of FIG. 8 according to an embodiment of the present disclosure.

FIGS. 10A and 10B are enlarged sectional views illustrating region AA of FIG. 8 according to comparative examples.

FIGS. 11A and 11B are sectional views illustrating optical paths according to a comparative example and an embodiment of the present disclosure, respectively.

FIGS. 12A and 12B are graphs depicting front light efficiency and light efficiency at a viewing angle of 45 degrees of the display device according to embodiments of the present disclosure.

FIGS. 13A and 13B are views illustrating light efficiency depending on a viewing angle according to embodiments of the present disclosure.

FIGS. 14A and 14B are views illustrating light efficiency depending on a viewing angle according to embodiments of the present disclosure.

FIG. 15 is a graph depicting front light efficiency depending on a side angle and a refractive index difference of the display device according to an embodiment of the present disclosure.

FIGS. 16A to 16F are graphs depicting light efficiency depending on a viewing angle of the display device according to an embodiment of the present disclosure.

FIG. 17 is a graph depicting light efficiency depending on a viewing angle of the display device according to an embodiment of the present disclosure.

FIG. 18 is a sectional view of the display device taken along line II-II′ of FIG. 7 according to another embodiment of the present disclosure.

FIG. 19 is a sectional view of the display device according to an embodiment of the present disclosure.

FIG. 20 is a sectional view of the display device taken along line II-II′ of FIG. 7 according to still another embodiment of the present disclosure.

FIG. 21 is a sectional view of the display device taken along line II-II′ of FIG. 7 according to yet another embodiment of the present disclosure.

### DETAILED DESCRIPTION

In this specification, when it is mentioned that a component (or, an area, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description. The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes all of one or more combinations defined by related components.

Terms such as “first”, “second”, and the like may be used to describe various components, but the components should not be limited by the terms. The terms may be used only for distinguishing one component from other components. For example, without departing the scope of the present disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship of components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

Hereinafter, embodiments of the present disclosure will be described with reference to the accompanying drawings.

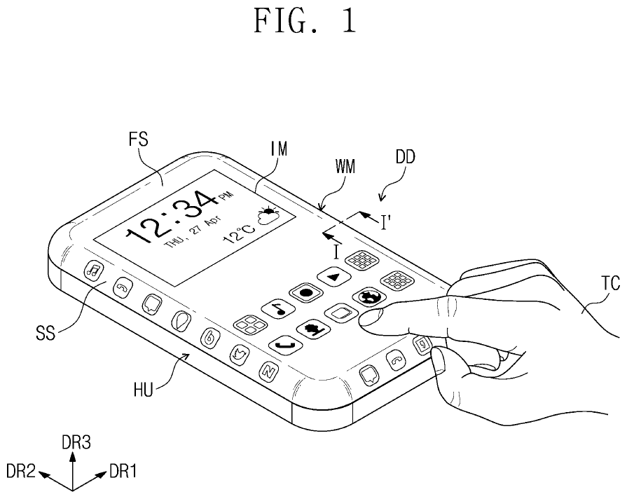

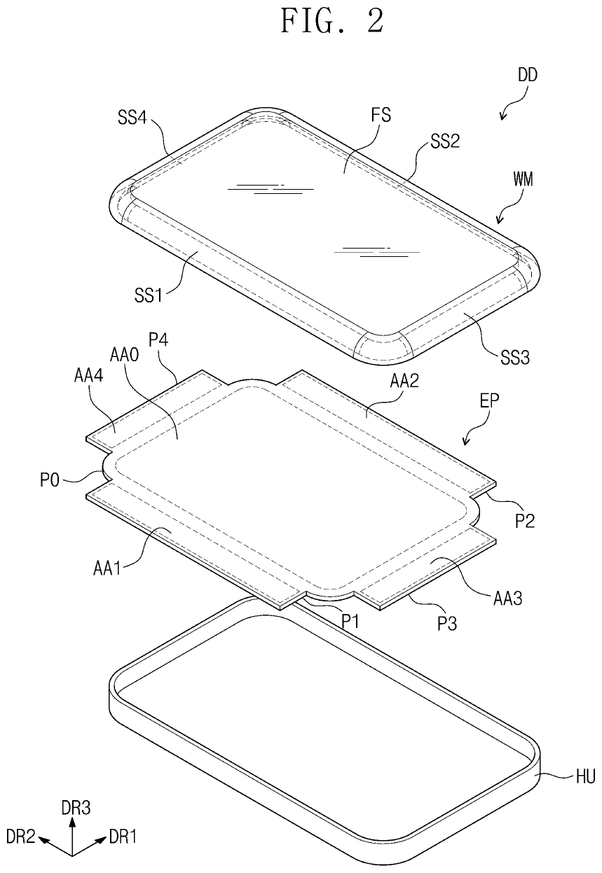

FIG. 1 is a perspective view of a display device according to an embodiment of the present disclosure. FIG. 2 is an exploded perspective view of the display device according to an embodiment of the present disclosure.

Referring to FIGS. 1 and 2, the display device DD may be activated depending on an electrical signal. For example, the display device DD may be a mobile phone, a tablet computer, a car navigation unit, a game machine, or a wearable device, but is not limited thereto. FIG. 1 illustrates an example that the display device DD is a mobile phone.

The display device DD may display an image IM and may sense a user input TC applied from the outside.

The image IM may be displayed on all surfaces of a window WM. For example, the image IM may be displayed on a front surface FS and a curved surface SS of the window WM. That is, the display device DD according to an embodiment of the present disclosure may correspond to what is called a multi-display device that displays an image on a front surface and four side surfaces SS1, SS2, SS3, and SS4. Although the multi-display device is illustrated in FIGS. 1 and 2, the display device DD according to an embodiment of the present disclosure that will be described below is not limited thereto and may be applied to a front display device.

The user input TC (hereinafter, referred to as the external input) includes various forms of external inputs such as a part of a user's body, light, heat, pressure, and the like. In addition, the display device DD may sense an input proximate or adjacent to the display device DD as well as an input in contact with the display device DD. In this embodiment, the display device DD is illustrated as a smart phone, and the external input TC is illustrated as a hand of the user. Meanwhile, in this embodiment, the external input TC may include force and touch.

The display device DD may sense the user input TC provided to all the surfaces of the window WM. In FIG. 1, for ease of description, the user input TC is illustrated as being provided on the front surface of the display device DD. However, the user input TC may be provided on the side surfaces of the display device DD, and the display device DD may easily sense information about the position and intensity of the external input TC provided on the side surfaces.

The display device DD may include the window WM, an electronic panel EP, an input sensing unit ISL, and a housing HU. The window WM and the housing HU may be coupled with each other to form an exterior of the display device DD. The window WM protects an upper surface of the electronic panel EP. The window WM may be optically clear. Accordingly, an image displayed on the electronic panel EP may be visible to the user through the window WM. The window WM may be formed of glass, plastic, or a film.

The window WM may include at least a portion curved on a section defined by a first direction DR1 and a second direction DR2. The window WM may include the front surface FS, the first side surface SS1, the second side surface SS2, the third side surface SS3, and the fourth side surface SS4.

In this embodiment, the front surface FS is illustrated as a surface perpendicular to a third direction DR3. The first side surface SS1, the second side surface SS2, the third side surface SS3, and the fourth side surface SS4 may be curved from the front surface FS. The first side surface SS1 and the second side surface SS2 may be surfaces curved from the front surface FS and perpendicular to the first direction DR1. The first side surface SS1 and the second side surface SS2 may be opposite each other in the first direction DR1.

The third side surface SS3 and the fourth side surface SS4 may be surfaces curved from the front surface FS and perpendicular to the second direction DR2. The third side surface SS3 and the fourth side surface SS4 may be opposite each other in the second direction DR2.

The electronic panel EP may include a main portion P0 and a plurality of cut-away portions P1, P2, P3, and P4. The main portion P0 may be disposed parallel to the front surface FS and may have a shape corresponding to the front surface FS. The main portion P0 may include a main active region AA0 for providing the image IM on the front surface FS.

The cut-away portions P1, P2, P3, and P4 may include the first to fourth cut-away portions P1, P2, P3, and P4. The first to fourth cut-away portions P1, P2, P3, and P4 are disposed on sides of the main portion P0 and protrude from the main portion P0.

In FIG. 2, for ease of description, the first to fourth cut-away portions P1, P2, P3, and P4 are illustrated parallel to the main portion P0. However, the first to fourth cut-away portions P1, P2, P3, and P4 may be assembled in a state of being bent from the main portion P0 to face toward the first to fourth side surfaces SS1, SS2, SS3, and SS4. The first to fourth cut-away portions P1, P2, P3, and P4 may include sub-active regions AA1, AA2, AA3, and AA4 for providing the image IM on the first to fourth side surfaces SS1, SS2, SS3, and SS4.

Meanwhile, this is illustrative, and the electronic panel EP may be assembled in various forms depending on the shape of the window WM. For example, only some of the cut-away portions P1, P2, P3, and P4 may be assembled in a state of being bent from the main portion P0, or all of the cut-away portions P1, P2, P3, and P4 may be assembled in a shape that defines the same plane as the main portion P0. The display device DD according to an embodiment of the present disclosure may be assembled in various forms depending on determined design and is not limited to any one embodiment. In this specification, hereinafter, the cut-away portions P1, P2, P3, and P4 of the electronic panel EP are not separately illustrated.

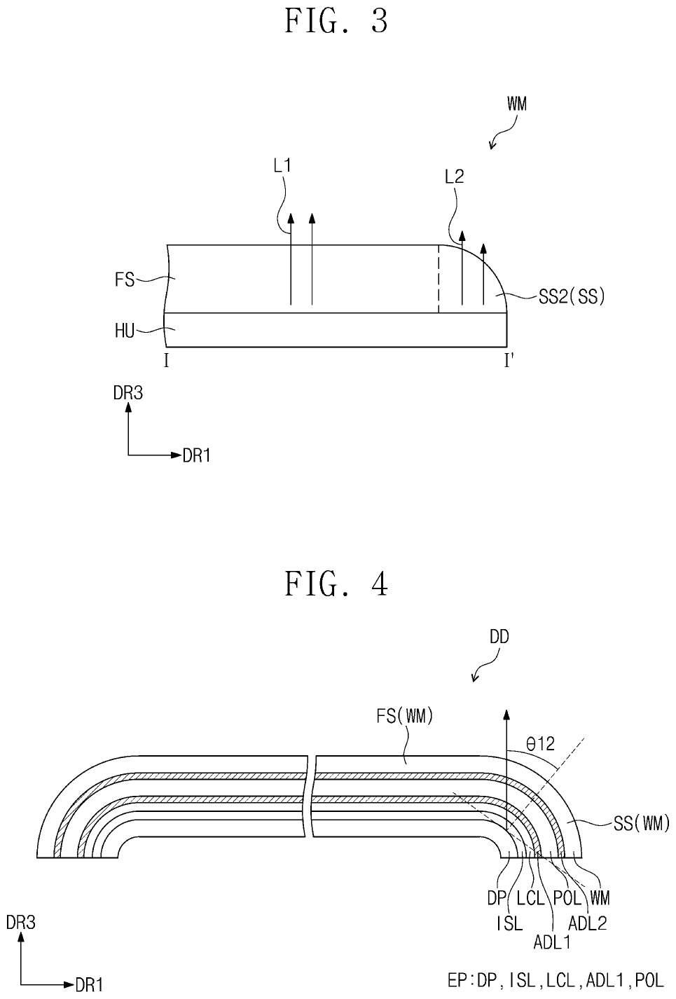

FIG. 3 is a sectional view taken along line I-I′ of FIG. 1 according to an embodiment of the present disclosure.

Referring to FIG. 3, light L1 output through the front surface FS of the window WM and light L2 output through the second side surface SS2 of the window WM may be identified. When the user views the display device DD of FIG. 1 from the front, the viewing angle of the light L1 output through the front surface FS may be 0 degrees. Here, the viewing angle may refer to an angle formed by the light with respect to a reference line perpendicular to a surface of a display panel DP (refer to FIG. 4).

When the user views the display device DD of FIG. 1 from the front, the viewing angle of the light L2 output through the second side surface SS2 may be more than 0 degrees and less than 90 degrees. The viewing angle of the light L2 output through the second side surface SS2 may be increased farther away from the front surface FS. Because light efficiency is decreased as a viewing angle is increased, the light efficiency of the light L2 output through the second side surface SS2 may be decreased farther away from the front surface FS. Hereinafter, light efficiency described in the present disclosure may refer to a luminance at a viewing angle of 0 degrees to 90 degrees when a luminance at the front (a viewing angle of 0 degrees) is 100%.

FIG. 4 is a sectional view of the display device according to an embodiment of the present disclosure. In FIG. 4, the display device DD is simply illustrated to explain a stacking relationship between a functional panel and functional units constituting the display device DD.

Referring to FIG. 4, the display device DD may include the display panel DP, the input sensing unit ISL, a light control layer LCL, and the window WM. The electronic panel EP may include the display panel DP, the input sensing unit ISL, the light control layer LCL, a first adhesive layer ADL1, and a polarization unit POL.

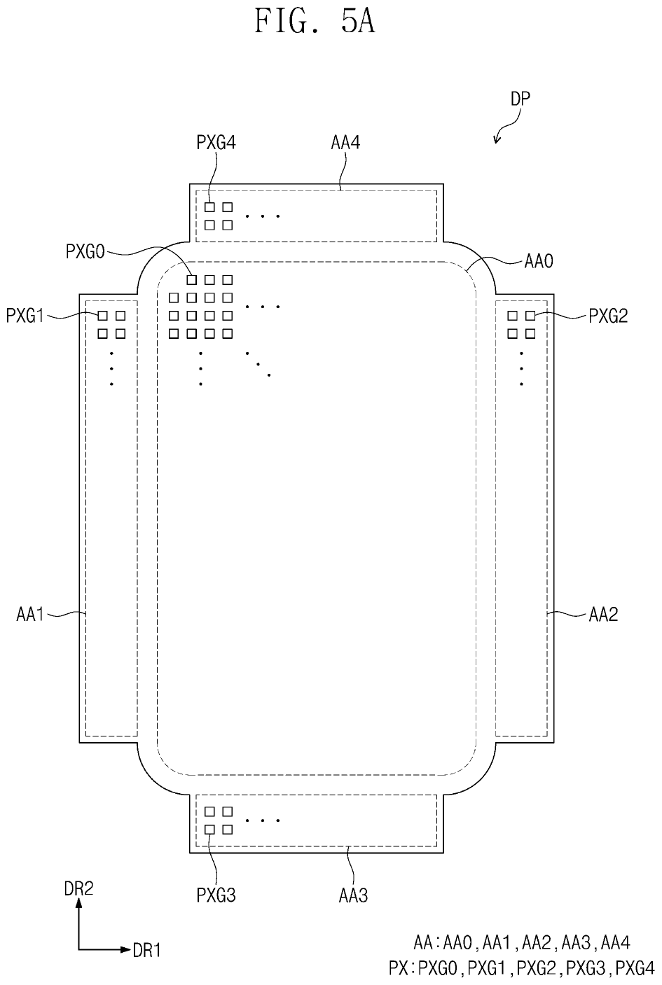

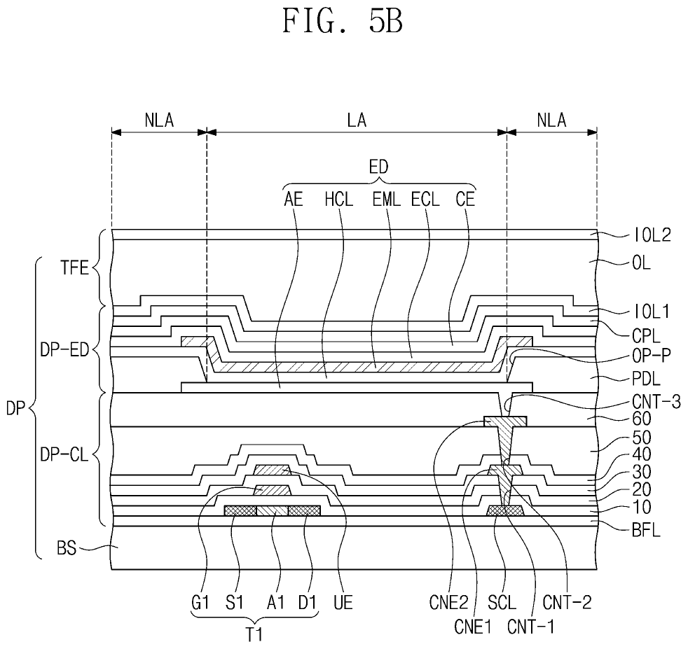

The display panel DP may generate an image. The display panel DP may include a plurality of pixels PX (refer to FIG. 5A). The display panel DP may be an emissive display panel including a light emitting element as a display element, but is not particularly limited thereto. For example, the display panel DP may be an organic light emitting display panel or an inorganic light emitting display panel. An emissive layer of the organic light emitting display panel may include an organic light emitting material. An emissive layer of the inorganic light emitting display panel may include a quantum dot, a quantum rod, or an inorganic LED. Hereinafter, the display panel DP will be described as an organic light emitting display panel.

The input sensing unit ISL may be disposed on the display panel DP. The input sensing unit ISL obtains coordinate information of an external input (e.g., a touch event). The input sensing unit ISL may sense the external input in a capacitive type.

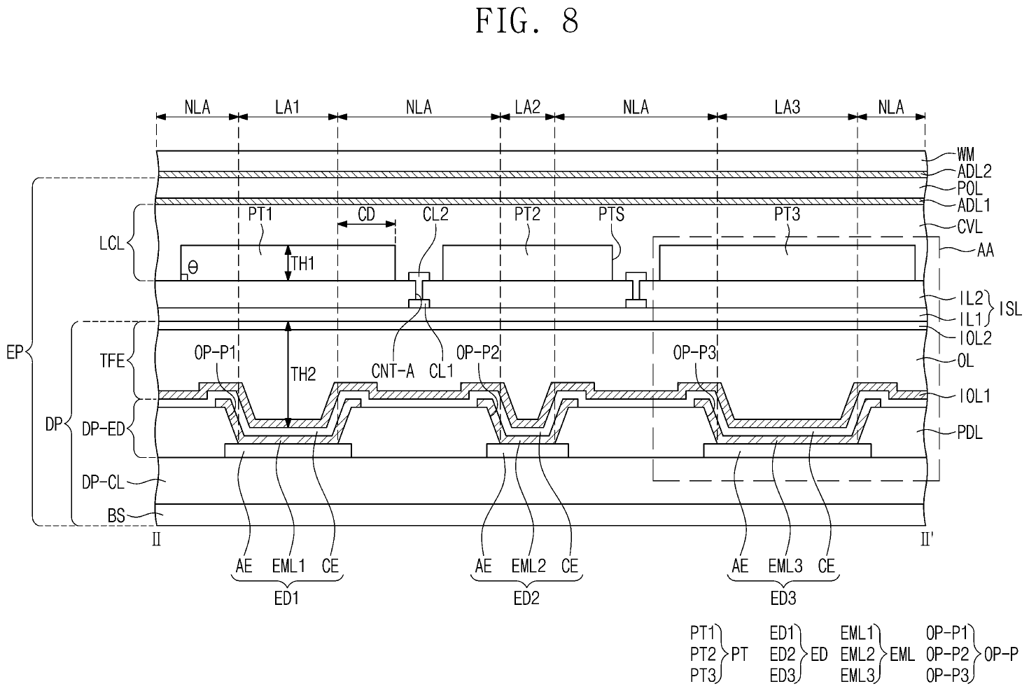

The light control layer LCL may be disposed on the input sensing unit ISL. The light control layer LCL may include a plurality of patterns and a layer having a refractive index different from those of the plurality of patterns. Description thereabout will be given below with reference to FIG. 8.

The polarization unit POL may be disposed on the light control layer LCL. The polarization unit POL may be attached to the light control layer LCL by the first adhesive layer ADL1. The first adhesive layer ADL1 may be a pressure sensitive adhesive (“PSA”) film or an optically clear adhesive (“OCA”). However, the first adhesive layer ADL1 may be omitted. The polarization unit POL may lower the reflectance of light incident from the outside. The polarization unit POL may include at least one of a phase retarder, a polarizer, a polarization film, and a polarization filter. However, the type of polarization unit POL is illustrative and is not limited thereto. For another example, the polarization unit POL may include color filters.

The window WM may be disposed on the polarization unit POL. The window WM may be attached to the polarization unit POL by a second adhesive layer ADL2. The upper surface of the window WM may include the flat front surface FS and the curved surface SS curved from the front surface FS. Distal ends of the display panel DP, the input sensing unit ISL, the light control layer LCL, and the polarization unit POL may be curved along the curved surface SS of the window WM.

When viewed from the front surface FS of the display device DD, the viewing angle θ12 of light output through the curved surface SS of the window WM may range from 0 degrees to 90 degrees. The viewing angle θ12 of the light output through the curved surface SS of the window WM may be about 45 degrees on average. Because the display panel DP for emitting light is curved with a curvature corresponding to the curvature of the curved surface SS, the viewing angle θ12 of the light output through the curved surface SS of the window WM may be increased farther away from the front surface FS.

FIG. 5A is a plan view of the display panel according to an embodiment of the present disclosure. As used herein, the “plan view” is defined as a view in a direction (third direction DR3) perpendicular to the front surface FS.

Referring to FIG. 5A, the display panel DP may include the plurality of pixels PX. The pixels PX may be disposed in an active region AA and may emit light. The pixels PX may be divided into a plurality of pixel groups PXG0, PXG1, PXG2, PXG3, and PXG4.

Among the pixel groups PXG0, PXG1, PXG2, PXG3, and PXG4, the main pixel group PXG0 may be disposed in the main active region AA0. An image displayed by the main pixel group PXG0 may be visible from the outside through the front surface FS (refer to FIG. 2).

Among the pixel groups PXG0, PXG1, PXG2, PXG3, and PXG4, the first sub-pixel group PXG1 may be disposed in the first sub-active region AA1. An image displayed by the first sub-pixel group PXG1 may be visible from the outside through the first side surface SS1 (refer to FIG. 2).

Among the pixel groups PXG0, PXG1, PXG2, PXG3, and PXG4, the second sub-pixel group PXG2 may be disposed in the second sub-active region AA2. An image displayed by the second sub-pixel group PXG2 may be visible from the outside through the second side surface SS2 (refer to FIG. 2).

Among the pixel groups PXG0, PXG1, PXG2, PXG3, and PXG4, the third sub-pixel group PXG3 may be disposed in the third sub-active region AA3. An image displayed by the third sub-pixel group PXG3 may be visible from the outside through the third side surface SS3 (refer to FIG. 2).

Among the pixel groups PXG0, PXG1, PXG2, PXG3, and PXG4, the fourth sub-pixel group PXG4 may be disposed in the fourth sub-active region AA4. An image displayed by the fourth sub-pixel group PXG4 may be visible from the outside through the fourth side surface SS4 (refer to FIG. 2).

The pixel groups PXG0, PXG1, PXG2, PXG3, and PXG4 may display images independent of one another, or may display images associated with one another. In an embodiment, for example, images displayed on the respective active regions AA0, AA1, AA2, AA3, and AA4 may display one image. Alternatively, an image including important information may be displayed on the main active region AA0, and an icon requiring a user input or a button image for controlling an image displayed on the main active region AA0 may be displayed on the first to fourth sub-active regions AA1, AA2, AA3, and AA4. The pixel groups PXG0, PXG1, PXG2, PXG3, and PXG4 may be connected to one drive circuit and driven through the one drive circuit or may be independently driven through separate independent drive circuits independent of one another and are not limited to any one embodiment.

FIG. 5B is a sectional view of the display panel according to an embodiment of the present disclosure.

Referring to FIG. 5B, the display panel DP may include a base layer BL, a circuit element layer DP-CL, a display element layer DP-ED, and a thin film encapsulation layer TFE.

The base layer BS may include a synthetic resin film. In addition, the base layer BS may include a glass substrate, a metal substrate, or an organic/inorganic composite substrate.

At least one inorganic layer is disposed on an upper surface of the base layer BS. The circuit element layer DP-CL may be disposed on the base layer BS. The circuit element layer DP-CL may include a buffer layer BFL and a plurality of insulating layers 10, 20, 30, 40, 50, and 60. The buffer layer BFL improves a coupling force between the base layer BS and a semiconductor pattern. The buffer layer BFL may include silicon oxide layers and silicon nitride layers. The silicon oxide layers and the silicon nitride layers may be alternately stacked one above another.

The display panel DP may include a plurality of insulating layers, the semiconductor pattern, a conductive pattern, and a signal line. An insulating layer, a semiconductor layer, and a conductive layer are formed by coating, deposition, or the like. Thereafter, the insulating layer, the semiconductor layer, and the conductive layer may be selectively subjected to patterning by photolithography and etching. The semiconductor pattern, the conductive pattern, and the signal line included in the circuit element layer DP-CL and the display element layer DP-ED are formed by the above-described method.

The semiconductor pattern is disposed on the buffer layer BFL. The semiconductor pattern may include poly-silicon. However, without being limited thereto, the semiconductor pattern may include amorphous silicon or metal oxide.

FIG. 5B illustrates only part of the semiconductor pattern, and in the plan view, the semiconductor pattern may be additionally disposed in a plurality of emissive regions LA1, LA2, and LA3 (refer to FIG. 8) that will be described below. The semiconductor pattern may be arranged across the plurality of emissive regions according to a specific rule. The semiconductor pattern has different electrical properties depending on whether the semiconductor pattern is doped or not. The semiconductor pattern may include a first region having a high doping concentration and a second region having a low doping concentration. The first region may be doped with an N-type dopant or a P-type dopant. A P-type transistor includes the first region doped with a P-type dopant.

The first region has a higher conductivity than the second region and substantially serves as an electrode or a signal line. The second region substantially corresponds to a channel region of a transistor. In other words, one portion of the semiconductor pattern may be the channel region of the transistor, another portion may be a source or drain region of the transistor, and another portion may be a conductive region.

As illustrated in FIG. 5B, a source region S1, a channel region A1, and a drain region D1 of a transistor T1 are formed from the semiconductor pattern. FIG. 5B illustrates a portion of a signal transmission region SCL formed from the semiconductor pattern. Although not separately illustrated, the signal transmission region SCL may be connected to the drain region D1 of the transistor T1 in the plan view.

The first to sixth insulating layers 10 to 60 are disposed on the buffer layer BFL. The first to sixth insulating layers 10 to 60 may be inorganic layers or organic layers. A gate G1 is disposed on the first insulating layer 10. An upper electrode UE may be disposed on the second insulating layer 20. A first connecting electrode CNE1 may be disposed on the third insulating layer 30. The first connecting electrode CNE1 may be connected to the signal transmission region SCL through a contact hole CNT-1 penetrating the first to third insulating layers 10 to 30. The fourth insulating layer 40 and the fifth insulating layer 50 may be disposed on the third insulating layer 30. According to an embodiment, the fourth insulating layer 40 and the fifth insulating layer 50 may be organic layers.

A second connecting electrode CNE2 may be disposed on the fifth insulating layer 50. The second connecting electrode CNE2 may be connected to the first connecting electrode CNE1 through a contact hole CNT-2 penetrating the fourth insulating layer 40 and the fifth insulating layer 50.

The display element layer DP-ED may be disposed on the circuit element layer DP-CL. According to this embodiment, the display element layer DP-ED may include a light emitting element ED, a pixel defining layer PDL, a capping layer CPL, and an anti-reflective layer INF.

The light emitting element ED is disposed on the sixth insulating layer 60. The light emitting element ED may overlap an emissive region LA. According to this embodiment, the light emitting element ED may include a first electrode AE, a hole control layer HCL, an emissive layer EML, an electron control layer ECL, and a second electrode CE.

The first electrode AE is disposed on the sixth insulating layer 60. The first electrode AE is connected to the second connecting electrode CNE2 through a contact hole CNT-3 penetrating the sixth insulating layer 60. The pixel defining layer PDL is disposed on the sixth insulating layer 60. A pixel opening OP-P is defined in the pixel defining layer PDL. The pixel opening OP-P exposes at least a portion of the first electrodes AE. Substantially, the “emissive region” LA may be defined to correspond to a portion of the first electrode AE exposed through the pixel opening OP-P. A non-emissive region NLA corresponds to a region other the emissive region LA in the active regions AA0 to AA4 (refer to FIG. 2).

In an embodiment, the pixel defining layer PDL may include a light absorbing material. The pixel defining layer PDL may include a black coloring agent. The black coloring agent may include a black dye or a black pigment. The black coloring agent may include carbon black, metal such as chromium, or oxide thereof.

The hole control layer HCL is disposed on the first electrode AE. The hole control layer HCL may be commonly disposed in the emissive region LA and the non-emissive region NLA. The hole control layer HCL may include a hole transport layer and may further include a hole injection layer.

The emissive layer EML is disposed on the hole control layer HCL. The emissive layer EML may be disposed in a region corresponding to the pixel opening OP-P. That is, the emissive layer EML may be disposed to correspond to the emissive region LA.

The electron control layer ECL is disposed on the emissive layer EML. The electron control layer ECL may include an electron transport layer and may further include an electron injection layer. The second electrode CE is disposed on the electron control layer ECL. The electron control layer ECL and the second electrode CE may be commonly disposed in the emissive region LA and the non-emissive region NLA.

The capping layer CPL is disposed on the second electrode CE. The capping layer CPL may be commonly disposed in the emissive region LA and the non-emissive region NLA.

According to an embodiment, the capping layer CPL may include an inorganic material. The capping layer CPL may be formed through a sputtering deposition process.

The capping layer CPL may protect the second electrode CE and the emissive layer EML from infiltration of external moisture or contamination by covering the second electrode CE. In addition, light totally reflected at the interface between the second electrode CE and the capping layer CPL may be reduced by adjusting the refractive index and thickness of the capping layer CPL.

The thin film encapsulation layer TFE may be disposed on the display element layer DP-ED. The thin film encapsulation layer TFE may seal the display element layer DP-ED. The thin film encapsulation layer TFE may include one layer or a plurality of layers stacked one above another. The thin film encapsulation layer TFE includes at least one organic film.

According to an embodiment, the thin film encapsulation layer TFE may include a first inorganic layer IOL1, an organic layer OL, and a second inorganic layer IOL2. The first inorganic layer IOL1 may be disposed on the capping layer CPL. The organic layer OL may be disposed on the first inorganic layer IOL1. The second inorganic layer IOL2 may be disposed on the organic layer OL and may cover the organic layer OL.

The first inorganic layer IOL1 and the second inorganic layer IOL2 may protect the display element layer DP-ED from moisture/oxygen, and the organic layer OL may protect the display element layer DP-ED from foreign matter such as dust particles.

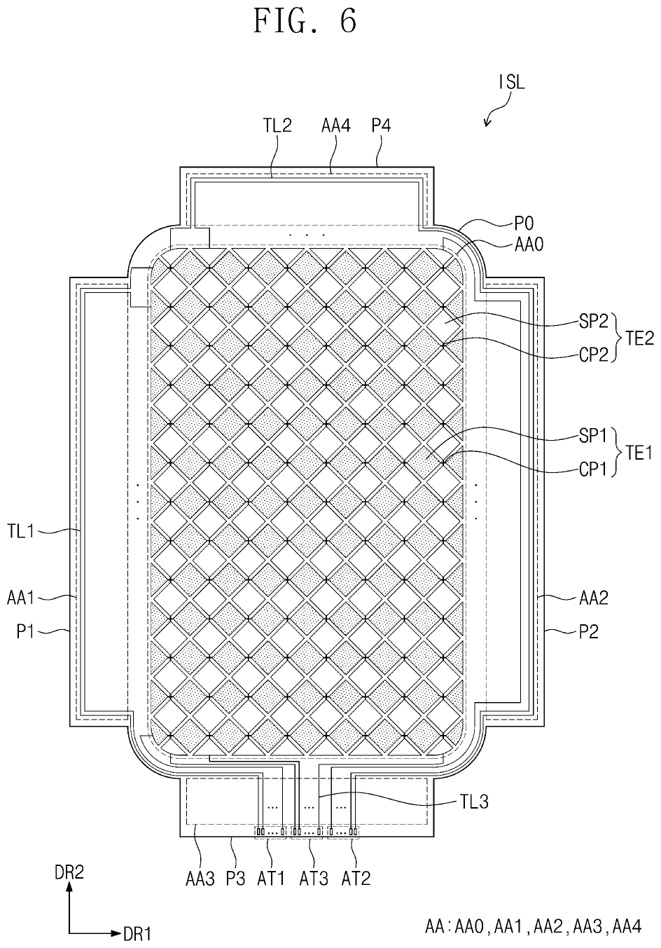

FIG. 6 is a plan view of the input sensing unit according to an embodiment of the present disclosure.

Referring to FIG. 6, the input sensing unit ISL senses the external input TC applied from the outside. Specifically, the input sensing unit ISL senses an input provided to the main active region AA0 through the front surface FS (refer to FIG. 2) of the window WM (refer to FIG. 2). Sensing the input provided to the main active region AA0 is illustrated. However, without being limited thereto, the input sensing unit ISL may sense inputs in the first to fourth sub-active regions AA1 to AA4 and is not limited to any one embodiment.

The input sensing unit ISL may include a plurality of first sensing electrodes TE1, a plurality of second sensing electrodes TE2, a plurality of sensing lines TL1, TL2, and TL3, and a plurality of sensing pads AT1, AT2, and AT3.

The first sensing electrodes TE1 and the second sensing electrodes TE2 may be disposed in the main active region AA0. The input sensing unit ISL may obtain information about the external input TC through a change in mutual capacitance between the first sensing electrodes TE1 and the second sensing electrodes TE2.

The first sensing electrodes TE1 are arranged in the second direction DR2, and each of the first sensing electrodes TEL extends in the first direction DR1. The first sensing electrode TE1 may include first sensing patterns SP1 and first connecting patterns CP1.

In this embodiment, the first sensing patterns SP1 may have a rhombic shape. However, this is illustrative, and the first sensing patterns SP1 may have various shapes and are not limited to any one embodiment.

The first connecting patterns CP1 are connected to the first sensing patterns SP1. Each of the first connecting patterns CP1 may be disposed between two first sensing patterns SP1 and may connect the two first sensing patterns SP1.

The second sensing electrodes TE2 are arranged in the first direction DR1, and each of the second sensing electrodes TE2 extends in the second direction DR2. The second sensing electrode TE2 may include second sensing patterns SP2 and second connecting patterns CP2.

The second sensing patterns SP2 may be spaced apart from the first sensing patterns SP1. The first sensing patterns SP1 and the second sensing patterns SP2 may be electrically isolated from each other. The first sensing patterns SP1 and the second sensing patterns SP2 may transmit/receive independent electrical signals without making contact with each other.

In this embodiment, the second sensing patterns SP2 may have the same shape as the first sensing patterns SP1. In an embodiment, for example, the second sensing patterns SP2 may have a rhombic shape. However, this is illustrative, and the second sensing patterns SP2 may have various shapes and are not limited to any one embodiment.

The second connecting patterns CP2 are connected to the second sensing patterns SP2. Each of the second connecting patterns CP2 may be disposed between two second sensing patterns SP2 and may connect the two second sensing patterns SP2.

In this embodiment, the first sensing patterns SP1 and the second sensing patterns SP2 may include an optically clear material. Accordingly, even though the first sensing patterns SP1 and the second sensing patterns SP2 are disposed to overlap the pixels PX (refer to FIG. 5A) in the plan view, the image IM displayed by the display panel DP (refer to FIG. 5A) may be easily visible to the user.

Alternatively, the first sensing patterns SP1 and the second sensing patterns SP2 may each include a plurality of mesh lines. The mesh lines define openings overlapping the emissive regions of the pixels PX (refer to FIG. 5A) in the plan view. Accordingly, the visibility of the image IM displayed by the display panel DP may be prevented from being degraded due to the input sensing unit ISL.

The sensing lines TL1, TL2, and TL3 may be disposed in regions other than the main active region AA0. Specifically, the sensing lines TL1, TL2, and TL3 may connect the first and second sensing electrodes TEL and TE2 and the sensing pads AT1, AT2, and AT3 via partial regions of the first to fourth sub-active regions AA1, AA2, AA3, and AA4. The sensing lines TL1, TL2, and TL3 may include the first sensing lines TL1, the second sensing lines TL2, and the third sensing lines TL3.

The first sensing lines TL1 are connected to the first sensing electrodes TE1, respectively. In this embodiment, the first sensing lines TL1 are connected to left ends of the first sensing electrodes TE1, respectively. The first sensing lines TL1 may be connected to the first sensing pads AT1, respectively, via the first sub-active region AA1 and the third sub-active region AA3.

The second sensing lines TL2 are connected to upper ends of the second sensing electrodes TE2, respectively. The second sensing lines TL2 connect the second sensing electrodes TE2 and the second sensing pads AT2, respectively. The second sensing lines TL2 may sequentially pass through partial regions of the fourth sub-active region AA4, the second sub-active region AA2, and the third sub-active region AA3 and may be connected to the second sensing pads AT2, respectively.

The third sensing lines TL3 are connected to lower ends of the second sensing electrodes TE2, respectively. The third sensing lines TL3 connect the second sensing electrodes TE2 and the third sensing pads AT3, respectively. The third sensing lines TL3 may be connected to the third sensing pads AT3, respectively, via the third sub-active region AA3.

According to the present disclosure, the second sensing electrodes TE2 may be connected to the second sensing lines TL2 and the third sensing lines TL3, respectively. Accordingly, sensitivities depending on regions may be uniformly maintained for the second sensing electrodes TE2 longer than the first sensing electrodes TE1. However, this is illustrative, and in the input sensing unit ISL according to an embodiment of the present disclosure, the third sensing lines TL3 may be omitted, and the present disclosure is not limited to any one embodiment.

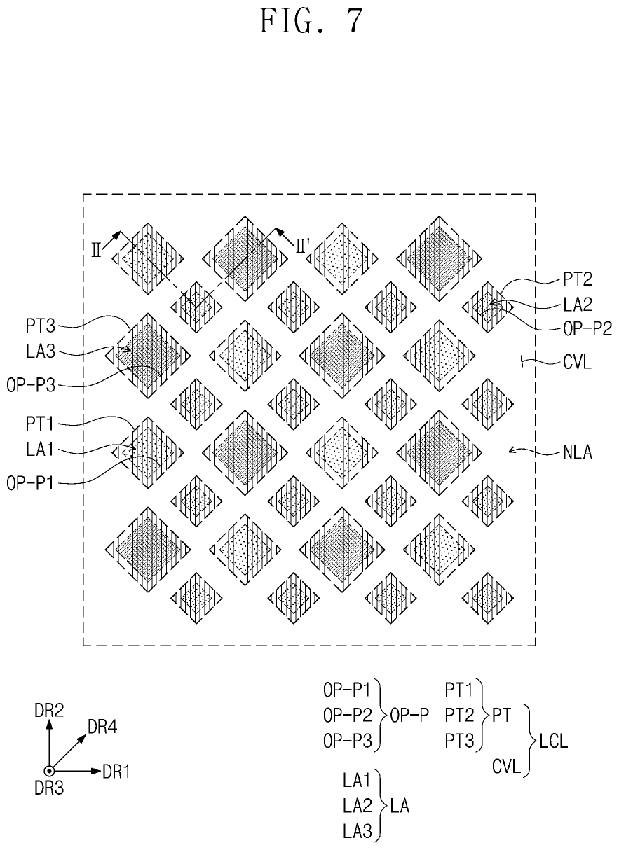

FIG. 7 is an enlarged plan view of the active region according to an embodiment of the present disclosure. FIG. 7 is a plan view of the emissive region LA, the non-emissive region NLA, and the light control layer LCL. The active region illustrated in FIG. 7 may correspond to the sub-active regions AA1, AA2, AA3, and AA4 described above with reference to FIG. 5A. However, without being limited thereto, the active region illustrated in FIG. 7 may be the main active region AA0 described above with reference to FIG. 5A and is not limited to any one embodiment.

Referring to FIG. 7, the pixel defining layer PDL (refer to FIG. 8) may define a plurality of pixel openings OP-P therein. The pixel openings OP-P may include a first pixel opening OP-P1, a second pixel opening OP-P2, and a third pixel opening OP-P3 having different areas in the plan view. According to an embodiment, in the plan view, the first pixel opening OP-P1 may have an area larger than the area of the second pixel opening OP-P2 and smaller than the area of the third pixel opening OP-P3.

Emissive regions LA may include first to third emissive regions LA1, LA2, and LA3. A non-emissive region NLA may be adjacent to the emissive regions LA. The first emissive region LA1 may be a region that a first electrode AE (refer to FIG. 8) exposed by the first pixel opening OP-P1 occupies in the plan view. The first emissive region LA1 may provide a first color light beam. The second emissive region LA2 may be a region that a first electrode AE (refer to FIG. 8) exposed by the second pixel opening OP-P2 occupies in the plan view. The second emissive region LA2 may provide a second color light beam. The third emissive region LA3 may be a region that a first electrode AE (refer to FIG. 8) exposed by the third pixel opening OP-P3 occupies in the plan view. The third emissive region LA3 may provide a third color light beam.

The first and third emissive regions LA1 and LA3 may be alternately arranged in the first direction DR1 in the plan view. The second emissive regions LA2 may be disposed in pixel rows different from the pixel rows in which the first and third emissive regions LA1 and LA3 are disposed. The second emissive regions LA2 may be arranged in the first direction DR1 in the same pixel row. The first and second emissive regions LA1 and LA2 may be alternately arranged in a fourth direction DR4 defined as an oblique direction inclined with respect to the first and second directions DR1 and DR2. The second and third emissive regions LA2 and LA3 may be alternately arranged in the fourth direction DR4. However, an arrangement of the first to third emissive regions LA1, LA2, and LA3 is not limited thereto.

The first to third color light beams may be light beams having different colors. In an embodiment, for example, the first color light beam provided by the first emissive region LA1 may be a red light beam, the second color light beam provided by the second emissive region LA2 may be a green light beam, and the third color light beam provided by the third emissive region LA3 may be a blue light beam.

However, without being limited thereto, the first to third color light beams may be selected as a combination of three color light beams that are mixed to generate white light. Alternatively, the first to third color light beams may be light beams having the same color.

The light control layer LCL may include a high refractive index pattern PT and a low refractive index layer CVL. In FIG. 7, the area occupied by the high refractive index pattern PT in the plan view is illustrated as first to third high refractive index patterns PT1, PT2, and PT3. The high refractive index pattern PT may cover the plurality of emissive regions LA in the plan view. The first high refractive index pattern PT1 may cover the first emissive region LA1 in the plan view. The second high refractive index pattern PT2 may cover the second emissive region LA2 in the plan view. The third high refractive index pattern PT3 may cover the third emissive region LA3 in the plan view.

FIG. 8 is a sectional view of the display device taken along line II-II′ of FIG. 7 according to an embodiment of the present disclosure.

Referring to FIGS. 7 and 8, the input sensing unit ISL may be disposed on the display panel DP. According to this embodiment, the input sensing unit ISL may be directly disposed on the thin film encapsulation layer TFE.

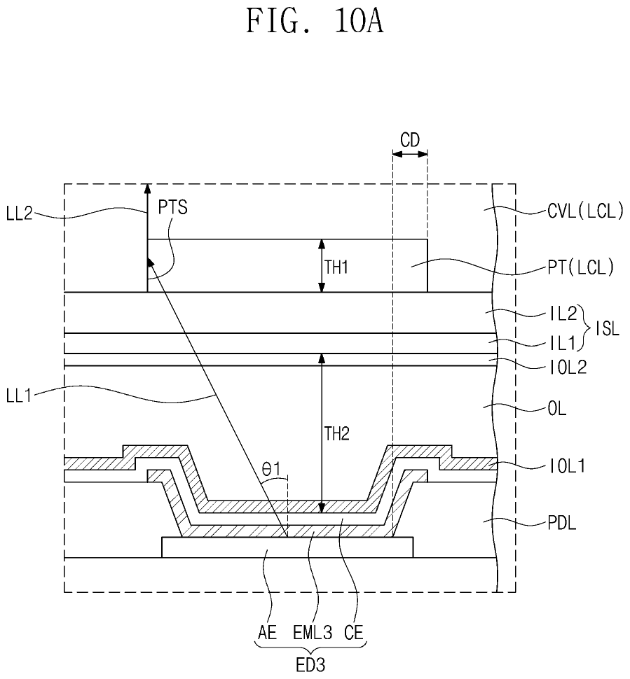

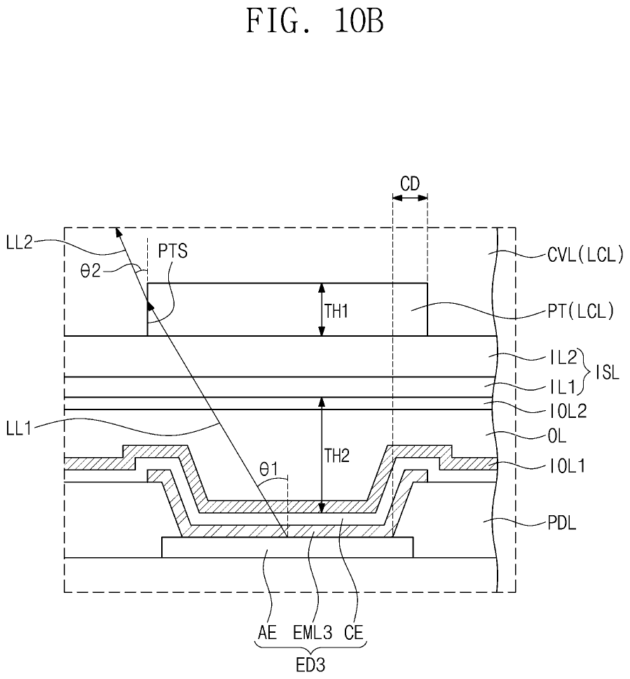

As described above with reference to FIG. 5B, the thin film encapsulation layer TFE may include the first inorganic layer IOL1, the organic layer OL, and the second inorganic layer IOL2. The thin film encapsulation layer TFE may have a thickness of 10 micrometers (μm) to 11 μm. The thickness of the thin film encapsulation layer TFE may be measured from a middle of the first electrode AE in a plan view (See TH2 in FIG. 8). When the thickness of the thin film encapsulation layer TFE is less than 10 μm or more than 11 μm, the viewing angle of light refracted and output through a side surface PTS may deviate from about 45 degrees. Description thereabout will be given with reference to FIGS. 10A and 10B.

According to this embodiment, the input sensing unit ISL may include a first sensing insulation layer IL1, a first conductive layer CL1, a second sensing insulation layer IL2, and a second conductive layer CL2. The first sensing insulation layer IL1 may be disposed on the thin film encapsulation layer TFE. The first conductive layer CL1 may be disposed on the first sensing insulation layer IL1. The first conductive layer CL1 may overlap the non-emissive region NLA. The second sensing insulation layer IL2 may be disposed on the first sensing insulation layer IL1 and may cover the first conductive layer CL1. The second conductive layer CL2 may be disposed on the second sensing insulation layer IL2 and may overlap the non-emissive region NLA. The second conductive layer CL2 may be electrically connected with the first conductive layer CL1 through a contact hole CNT-A defined through the second sensing insulation layer IL2.

Each of the first sensing insulation layer IL1 and the second sensing insulation layer IL2 may include at least one of an inorganic material and an organic material. Each of the first conductive layer CL1 and the second conductive layer CL2 may have conductivity and may be provided as a single layer or a plurality of layers.

At least one of the first conductive layer CL1 and the second conductive layer CL2 may be provided as mesh lines in the plan view. The mesh lines may be spaced apart from an emissive layer EML in the plan view. Accordingly, even though the input sensing unit ISL is directly disposed on the display panel DP, light generated from a light emitting element ED may be provided to the user without interference of the input sensing unit ISL. The emissive layer EML may include first to third emissive layers EML1, EML2, and EML3, and the light emitting element ED may include first to third light emitting elements ED1, ED2 and ED3.

The light control layer LCL may be disposed on the input sensing unit ISL. According to this embodiment, the light control layer LCL may include the high refractive index pattern PT and the low refractive index layer CVL.

The high refractive index pattern PT may be disposed on the second sensing insulation layer IL2. The high refractive index pattern PT may include the first to third high refractive index patterns PT1, PT2, and PT3.

According to an embodiment, the high refractive index pattern PT may include the first high refractive index pattern PT1, the second high refractive index pattern PT2, and the third high refractive index pattern PT3. In the plan view, the first high refractive index pattern PT1 may overlap the first pixel opening OP-P1, the second high refractive index pattern PT2 may overlap the second pixel opening OP-P2, and the third high refractive index pattern PT3 may overlap the third pixel opening OP-P3.

In the plan view, the first high refractive index pattern PT1 may overlap the entire area of the first emissive region LA1, the second high refractive index pattern PT2 may overlap the entire area of the second emissive region LA2, and the third high refractive index pattern PT3 may overlap the entire area of the third emissive region LA3. The first high refractive index pattern PT1 may have a shape corresponding to the first emissive region LA1 and may have a larger size than the first emissive region LA1. The second high refractive index pattern PT2 may have a shape corresponding to the second emissive region LA2 and may have a larger size than the second emissive region LA2. The third high refractive index pattern PT3 may have a shape corresponding to the third emissive region LA3 and may have a larger size than the third emissive region LA3.

The first to third high refractive index patterns PT1, PT2, and PT3 may have an arrangement corresponding to the arrangement of the first to third emissive regions LA1, LA2, and LA3 (refer to FIG. 7). However, the arrangement of the first to third high refractive index patterns PT1, PT2, and PT3 is not limited thereto and may vary depending on the arrangement of the first to third emissive regions LA1, LA2, and LA3.

The low refractive index layer CVL may cover the high refractive index pattern PT and the second conductive layer CL2. The low refractive index layer CVL may have a stepped lower surface due to the high refractive index pattern PT and the second conductive layer CL2, and an upper surface of the low refractive index layer CVL may be flat. The low refractive index layer CVL may overlap the non-emissive region NLA and the emissive region LA.

The high refractive index pattern PT and the low refractive index layer CVL may have different refractive indexes. The high refractive index pattern PT may have a first refractive index, and the low refractive index layer CVL may have a second refractive index lower than the first refractive index. The first refractive index may range from 1.5 to 1.8. The second refractive index may range from 1.3 to 1.5. Specifically, for light in a wavelength range of 550 nm to 660 nm, the first refractive index may range from 1.5 to 1.8, and the second refractive index may range from 1.3 to 1.5. As the first refractive index and the second refractive index satisfy the ranges, emission efficiency of light having a viewing angle of 45 degrees may be improved. A difference between the first refractive index and the second refractive index may be 0.25 or less. When there is a large difference between the first refractive index and the second refractive index, the amount of light totally reflected at the side surface PTS of the high refractive index pattern PT may be increased, and therefore light efficiency of the display device DD may be reduced.

Light that is generated from the light emitting element ED and that travels in a lateral direction may be refracted at the side surface PTS of the high refractive index pattern PT. In this case, by adjusting the position of the side surface PTS, the light refracted at the side surface PTS may improve light emission efficiency in a lateral direction having a viewing angle of 45 degrees. That is, the position of the side surface PTS may be adjusted to increase the percentage of light travelling in the lateral direction having a viewing angle of 45 degrees.

The separation distance CD by which the side surface PTS of the high refractive index pattern PT is spaced apart from one side surface of the emissive region LA closest to the side surface PTS in the plan view may range from 6 μm to 9 μm. When the separation distance CD is less than 6 μm, the viewing angle of light refracted at the side surface PTS and output to the outside may be decreased. When the separation distance CD exceeds 9 μm, the viewing angle of light refracted at the side surface PTS and output to the outside may be increased. Accordingly, to increase the percentage of light having a viewing angle of about 45 degrees that is output to the curved surface SS of the window WM of FIG. 3, it may be appropriate that the separation distance CD ranges from 6 μm to 9 μm.

As the difference in refractive index between the high refractive index pattern PT and the low refractive index layer CVL is increased, the amount by which light travelling in the lateral direction is refracted at the side surface PT of the high refractive index pattern PT may be increased.

The high refractive index pattern PT may have a thickness of 2 μm to 5 μm. The thickness of the high refractive index pattern PT may refer to the maximum thickness between the upper surface and the lower surface of the high refractive index pattern PT. When the thickness of the high refractive index pattern PT is less than 2 μm, the area of the side surface PTS may be decreased, and therefore the amount of light output through the side surface PTS may be reduced. In this case, it is difficult to effectively raise light efficiency of light output from the curved surface SS of the window WM of FIG. 2. When the thickness of the high refractive index pattern PT exceeds 5 μm, it may be difficult to implement the high refractive index pattern PT in a process. In an embodiment, for example, a deep portion of the high refractive index pattern PT may not be sufficiently cured by exposure in a general photolithography process. In addition, process accuracy may be reduced, which may lead to a reduction in process yield.

A side angle θ formed by the side surface PTS of the high refractive index pattern PT with respect to the upper surface of the second sensing insulation layer IL2 may range from 60 degrees to 90 degrees. When the side angle θ is less than 60 degrees, light refracted through the side surface PTS may be refracted to an excessively high degree. When the side angle θ exceeds 90 degrees, light refracted through the side surface PTS may be refracted to an excessively small degree. Accordingly, it may be appropriate that the side angle θ ranges from 60 degrees to 90 degrees such that the viewing angle of light refracted through the side surface PTS is about 45 degrees.

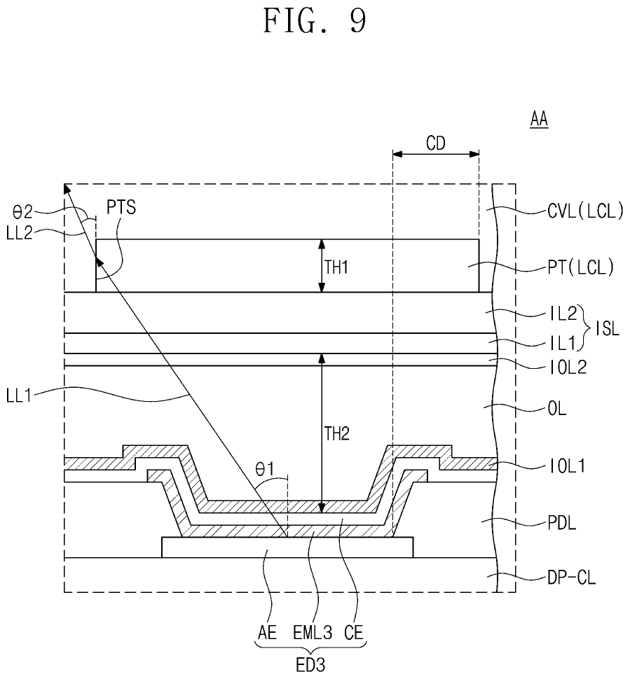

FIG. 9 is an enlarged sectional view illustrating region AA of FIG. 8 according to an embodiment of the present disclosure.

Referring to FIG. 9, a path of light LL1 and LL2 refracted through the side surface PTS of the high refractive index pattern PT may be identified. The light LL1 output from a third emissive layer EML3 may be refracted at the side surface PTS of the high refractive index pattern PT that differs from the low refractive index layer CVL in terms of refractive index. The viewing angle θ1 of the light LL1 output from the third emissive layer EML3 may be smaller than the viewing angle θ2 of the light LL2 refracted at the side surface PTS of the high refractive index pattern PT. This is because the refractive index of the high refractive index pattern PT is greater than the refractive index of the low refractive index layer CVL.

In the present disclosure, the separation distance CD may range from 6 μm to 9 μm and may be large. Because the separation distance CD is large, the viewing angle θ1 of the light LL1 incident to the side surface PTS may be greater than the corresponding viewing angle when the separation distance CD is small. Description thereabout will be given below with reference to FIG. 10A.

FIGS. 10A and 10B are enlarged sectional views illustrating region AA of FIG. 8 according to comparative examples.

Referring to FIGS. 9 and 10A, the separation distance CD in FIG. 10A may be smaller than the separation distance CD in FIG. 9. Accordingly, the viewing angle θ1 of the light LL1 incident to the side surface PTS may be smaller than the corresponding viewing angle in FIG. 9. When the viewing angle of the light LL2 refracted at the side surface PTS is 0 degrees as illustrated in FIG. 10A, the light efficiency of the light L1 output through the front surface FS of FIG. 3 may be increased. When the viewing angle θ2 of the light LL2 refracted at the side surface PTS has a value (about 45 degrees) greater than 0 degrees as illustrated in FIG. 9, the light efficiency of the light L2 output through the side surface SS of FIG. 3 may be increased. That is, when the separation distance CD is decreased (FIG. 10A), the viewing angle of light by which light efficiency increases may be decreased. When the separation distance CD is increased (FIG. 9), the viewing angle of light by which light efficiency increases may be increased.

In the present disclosure, by setting the separation distance CD to 6 μm to 9 μm, the light efficiency may be increased when the viewing angle is about 45 degrees. Description thereabout will be given below with reference to graphs.

Referring to FIGS. 10A and 10B, the thickness TH2 of the thin film encapsulation layer TFE in FIG. 10B may be smaller than the thickness TH2 of the thin film encapsulation layer TFE in FIG. 10A. Even when the thickness of the thin film encapsulation layer TFE is decreased, the viewing angle θ1 of the light LL1 incident to the side surface PTS may be increased similarly to when the separation distance CD is increased as illustrated in FIG. 9. In the present disclosure, by setting the thickness TH2 of the thin film encapsulation layer TFE to 10 μm to 11 μm, the light efficiency may be increased when the viewing angle is about 45 degrees. Description thereabout will be given below with reference to graphs.

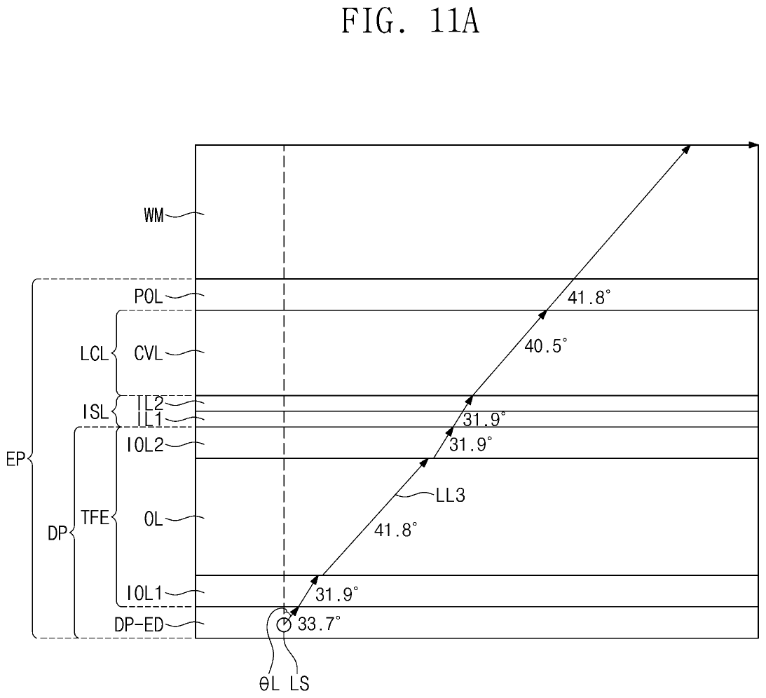

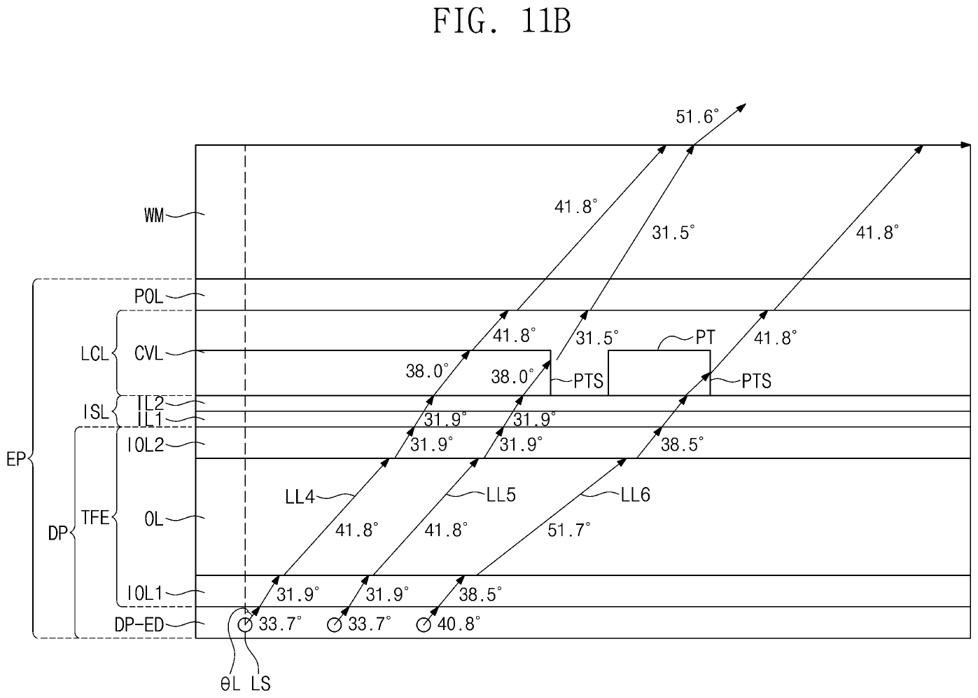

FIGS. 11A and 11B are sectional views illustrating optical paths according to a comparative example and an embodiment of the present disclosure, respectively.

Referring to FIG. 11A, a refraction path of light emitted from a display element layer DP-ED according to the comparative example may be identified. Here, the display element layer DP-ED may have a refractive index of about 1.8. A first inorganic layer IOL1 may have a refractive index of about 1.89. An organic layer OL may have a refractive index of about 1.5. A second inorganic layer IOL2 and an input sensing unit ISL may have a refractive index of about 1.89. A low refractive index layer CVL may have a refractive index of about 1.54. A polarization unit POL may have a refractive index of about 1.5. A window WM may have a refractive index of about 1.5. Although not illustrated above the window WM, an outer space may have a refractive index of about 1.

Light LL3 output from a light source LS at a viewing angle θL of 33.7 degrees may be refracted at a viewing angle of 31.9 degrees at the interface between the display element layer DP-ED and the first inorganic layer IOL1. The light LL3 may be refracted at viewing angles θL of 41.8 degrees, 31.9 degrees, 40.5 degrees, and 41.8 degrees at the interfaces between the layers. The light refracted at an angle of 41.8 degrees at the interface between the low refractive index layer CVL and the polarization unit POL may travel through the window WM. However, the light LL3 may be totally reflected at the interface between the outside and the window WM. That is, the light LL3 passing through the layers having the above-described refractive indexes in FIG. 11A may be totally reflected when the viewing angle θ1 at the light source LS exceeds 33.7 degrees.

That is, when the viewing angle θ1 at the light source LS ranges from 0 degrees to 33.7 degrees, light may be visible from outside the display device DD (refer to FIG. 1).

Referring to FIG. 11B, paths of light LL4, LL5, and LL6 in the display device DD including the high refractive index pattern PT and the low refractive index layer CVL according to an embodiment of the present disclosure may be identified. In FIG. 11B, the low refractive index layer CVL may have a refractive index of about 1.5, the high refractive index pattern PT may have a refractive index of about 1.623, and the polarization unit POL may have a refractive index of about 1.5. The refractive indexes of the other layers may be the same as the refractive indexes of the layers of FIG. 11A. If the light LL4 output from a light source LS at a viewing angle θL of 33.7 degrees passes through the upper surface of the high refractive index pattern PT, the light LL4 may be totally reflected at the interface between the window WM and the outside as in FIG. 11A.

When the light LL5 output from the light source LS at a viewing angle θL of 33.7 degrees is refracted at the side surface PTS of the high refractive index pattern PT, the light LL5 may travel toward the outside at a viewing angle θL of 51.6 degrees without being totally reflected at the interface between the window WM and the outside. That is, even though the light LL4 and LL5 is output from the light source LS at the same viewing angle θL of 33.7 degrees, the light LL5 may be visible from the outside when refracted through the side surface PTS of the high refractive index pattern PT.

When the light LL6 output from the light source LS at a viewing angle θL of 40.8 degrees is refracted at the side surface PTS of the high refractive index pattern PT, the light LL6 may be totally reflected at the interface between the window WM and the outside. That is, it can be seen that when the viewing angle θL at the light source LS exceeds 40.8 degrees, light is totally reflected and fails to travel to the outside even though the light is refracted at the side surface PTS of the high refractive index pattern PT.

The light LL4, LL5, and LL6 output from the light source LS may be visible from the outside when the viewing angle θL ranges from 0 degrees to 40.8 degrees. It can be seen that the range of the viewing angle θL is increased by about 7.1 degrees when compared to the range of 0 degrees to 33.7 degrees in the comparative example of FIG. 11A in which the high refractive index pattern PT does not exist. Accordingly, light not visible from the outside due to total reflection may be visible from the outside and may contribute to outcoupling efficiency of the entire display device DD (refer to FIG. 1).

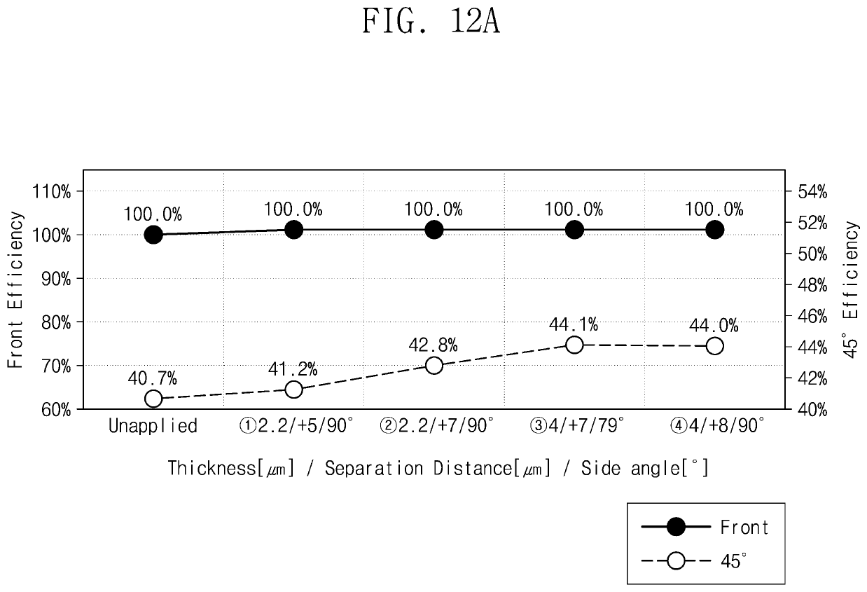

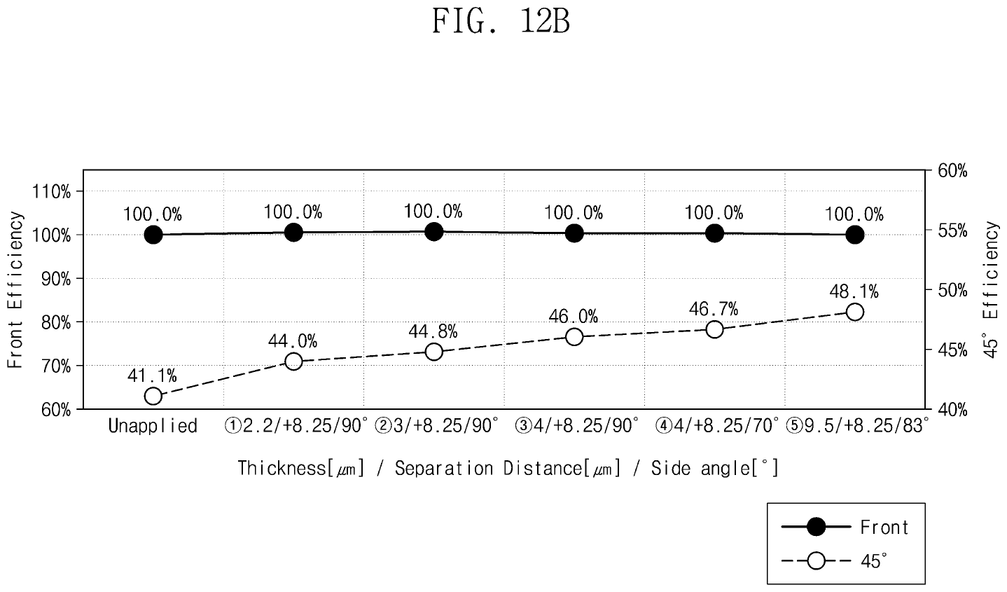

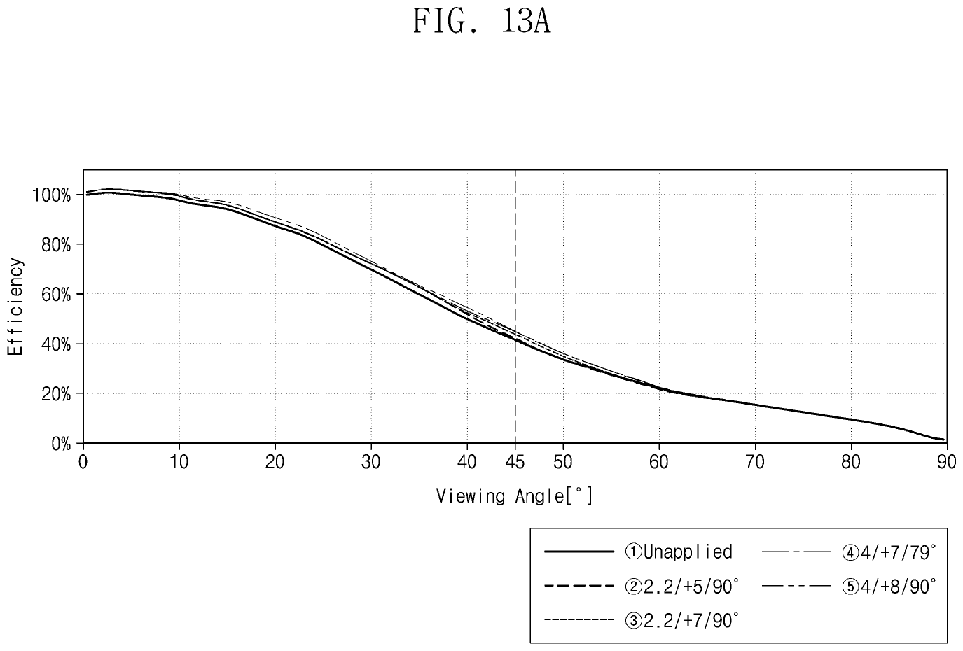

FIGS. 12A and 12B are graphs depicting front light efficiency and light efficiency at a viewing angle of 45 degrees of the display device according to embodiments of the present disclosure. More specifically, FIG. 12A is a graph depicting front light efficiency and light efficiency at a viewing angle of 45 degrees of the display device when the first high refractive index pattern PT1 (refer to FIG. 8) covering the first emissive region LA1 (refer to FIG. 8) for emitting red light is applied.

Here, the front efficiency may represent the luminance of the display device DD (refer to FIG. 1) when the display device DD (refer to FIG. 1) is viewed from the front. When the display device DD (refer to FIG. 1) is viewed from the front, this may mean that the user views the front surface FS (refer to FIG. 1) of the window WM (refer to FIG. 1). The 45-degree efficiency may refer to the ratio between the luminance of the display device DD (refer to FIG. 1) when the display device DD (refer to FIG. 1) is tilted at an angle of 45 degrees and viewed and the front efficiency. That is, when the 45-degree efficiency is 50%, this may mean that when the display device DD (refer to FIG. 1) is tilted at an angle of 45 degrees and viewed, the luminance of the display device DD (refer to FIG. 1) is decreased by 50% as compared with when the display device DD (refer to FIG. 1) is viewed from the front. Hereinafter, light efficiency described in the present disclosure may refer to a luminance at a viewing angle of 0 degrees to 90 degrees when a luminance at the front (at a viewing angle of 0 degrees) is 100%.

The graph of FIG. 12A depicts front efficiencies and 45-degree efficiencies obtained by carrying out simulation while changing the thickness TH1, the separation distance CD, and the side angle θ of the high refractive index pattern PT of FIG. 8.

In a comparative example, the high refractive index pattern PT (refer to FIG. 8) is not applied. In embodiment 1 (\textcircled{1}), the thickness TH1 is 2.2 μm, the separation distance CD is 5 μm, and the side angle θ is 90 degrees. In embodiment 2 (\textcircled{2}), the thickness TH1 is 2.2 μm, the separation distance CD is 7 μm, and the side angle θ is 90 degrees. In embodiment 3 (\textcircled{3}), the thickness TH1 is 4 μm, the separation distance CD is 7 μm, and the side angle θ is 79 degrees. In embodiment 4 (\textcircled{4}), the thickness TH1 is 4 μm, the separation distance CD is 8 μm, and the side angle θ is 90 degrees.

Referring to FIGS. 8 and 12A, it can be seen that the 45-degree efficiencies in embodiments 1 (\textcircled{1}) to 4 (\textcircled{4}) to which the high refractive index pattern PT is applied are higher than the 45-degree efficiency in the comparative example to which the high refractive index pattern PT is not applied. Referring to embodiment 1 (\textcircled{1}) and embodiment 2 (\textcircled{2}), it can be seen that when the separation distance CD is increased from 5 μm to 7 μm under the same condition, the 45-degree efficiency is increased from 41.2% to 42.8%. When embodiment 3 (\textcircled{3}) is compared with embodiment 2 (\textcircled{2}), the thickness TH1 is increased from 2.2 μm to 4 μm, and the side angle θ is decreased from 90 degrees to 79 degrees. In this case, the 45-degree efficiency is increased to 44.1%. When embodiment 4 (\textcircled{2}) is compared with embodiment 3 (\textcircled{3}), the separation distance CD is increased from 7 μm to 8 μm, and the side angle θ is increased from 79 degrees to 90 degrees. In this case, the 45-degree efficiency is decreased to 44.0%. Referring to FIGS. 8 and 12A, it can be seen that the 45-degree efficiency has the highest value of 44.1% when the first high refractive index pattern PT1 has a thickness TH1 of 4 μm, a separation distance of 7 μm, and a side angle θ of 79 degrees.

FIG. 12B is a graph depicting front light efficiency and light efficiency at a viewing angle of 45 degrees of the display device when the second high refractive index pattern PT2 (refer to FIG. 8) covering the second emissive region LA2 (refer to FIG. 8) for emitting green light is applied.

The graph of FIG. 12B depicts front efficiencies and 45-degree efficiencies obtained by carrying out simulation while changing the thickness TH1, the separation distance CD, and the side angle θ of the high refractive index pattern PT of FIG. 8.

In a comparative example, the high refractive index pattern PT (refer to FIG. 8) is not applied. In embodiment 1 (\textcircled{1}), the thickness TH1 is 2.2 μm, the separation distance CD is 8.25 μm, and the side angle θ is 90 degrees. In embodiment 2 (\textcircled{2}), the thickness TH1 is 3 μm, the separation distance CD is 8.25 μm, and the side angle θ is 90 degrees. In embodiment 3 (\textcircled{3}), the thickness TH1 is 4 μm, the separation distance CD is 8.25 μm, and the side angle θ is 90 degrees. In embodiment 4 (\textcircled{4}), the thickness TH1 is 4 μm, the separation distance CD is 8.25 μm, and the side angle θ is 70 degrees. In embodiment 5 (\textcircled{5}), the thickness TH1 is 9.5 μm, the separation distance CD is 8.25 μm, and the side angle θ is 83 degrees.

Referring to FIGS. 8 and 12B, it can be seen that the 45-degree efficiencies in embodiments 1 (\textcircled{1}) to 5 (\textcircled{5}) to which the high refractive index pattern PT is applied are higher than the 45-degree efficiency in the comparative example to which the high refractive index pattern PT is not applied. It can be seen that among the embodiments to which the high refractive index pattern PT is applied, embodiment 1 (\textcircled{1}) has the lowest 45-degree efficiency of 44% and embodiment 5 (\textcircled{5}) has the highest 45-degree efficiency of 48.1%. However, as described above, when the thickness TH1 exceeds 5 μm, it may be difficult to implement the high refractive index pattern PT in a process. Accordingly, embodiment 4 (4)) having the second highest 45-degree efficiency of 46.7% may be more appropriate. Referring to embodiment 2 (\textcircled{2}) and embodiment 3 (\textcircled{3}), the high refractive index pattern PT in embodiment 2 (\textcircled{2}) and the high refractive index pattern PT in embodiment 3 (\textcircled{3}) have the same separation distance CD of 8.25 μm and the same side angle θ of 90 degrees and have different thicknesses TH1 of 3 μm and 4 μm. The 45-degree efficiency in embodiment 2 (\textcircled{2}) is 44.8%, and the 45-degree efficiency in embodiment 3 (\textcircled{3}) is 46% that is higher than the 45-degree efficiency in embodiment 2 (\textcircled{2}). Accordingly, it can be seen that the 45-degree efficiency is increased as the thickness TH1 is increased.

Table 1 below shows light efficiencies depending on viewing angles that are obtained by carrying out simulation while changing the thickness TH1, the separation distance CD, and the side angle θ of the high refractive index pattern PT of FIG. 8. More specifically, Table 1 below shows simulation results of light efficiencies of the display device depending on viewing angles when the first high refractive index pattern PT1 (refer to FIG. 8) covering the first emissive region LA1 (refer to FIG. 8) for emitting red light is applied.

In the comparative example, the first high refractive index pattern PT1 (refer to FIG. 8) is not applied. In embodiment 1 (\textcircled{1}), the first high refractive index pattern PT1 (refer to FIG. 8) has a thickness TH1 of 2.2 μm, a separation distance CD of 5 μm, and a side angle θ of 90 degrees. In embodiment 2 (\textcircled{2}), the first high refractive index pattern PT1 (refer to FIG. 8) has a thickness TH1 of 2.2 μm, a separation distance CD of 7 μm, and a side angle θ of 90 degrees. In embodiment 3 (\textcircled{3}), the first high refractive index pattern PT1 (refer to FIG. 8) has a thickness TH1 of 4 μm, a separation distance CD of 7 μm, and a side angle θ of 79 degrees. In embodiment 4 (\textcircled{4}), the first high refractive index pattern PT1 (refer to FIG. 8) has a thickness TH1 of 4 μm, a separation distance CD of 8 μm, and a side angle θ of 90 degrees.

TABLE 1

| | | Comparative | Embodiment | Embodiment | Embodiment | Embodiment |
|---|---|---|---|---|---|---|
| | | example | 1 (\textcircled{1}) | 2 (\textcircled{2}) | 3 (\textcircled{3}) | 4 (\textcircled{4}) |
| Thickness (μm) | | — | 2.2 | 2.2 | 4 | 4 |
| Separation | | — | 5 | 7 | 7 | 8 |
| distance (μm) | | | | | | |
| Side angle | | — | 90 | 90 | 79 | 90 |
| (degree) | | | | | | |
| Viewing | 0.5 | 100.0% | 101.2% | 101.2% | 101.2% | 101.2% |
| angle | 15.5 | 93.6% | 96.5% | 95.2% | 95.2% | 95.2% |
| (degree) | 30.5 | 68.9% | 72.2% | 71.4% | 71.6% | 71.3% |
| | 45.5 | 40.7% | 41.2% | 42.8% | 44.1% | 44.0% |
| | 60.5 | 21.5% | 21.2% | 21.6% | 21.6% | 22.0% |

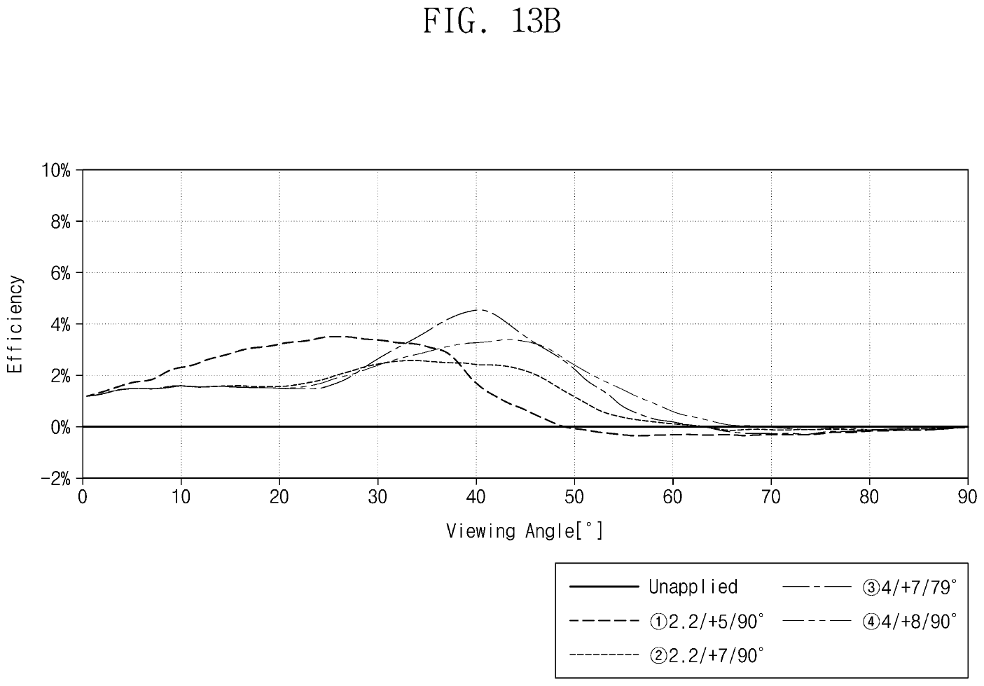

FIGS. 13A and 13B are views illustrating light efficiency depending on a viewing angle according to embodiments of the present disclosure. FIGS. 13A and 13B are graphs depicting the values in Table 1 above. FIG. 13B is a graph depicting differences in efficiency between the case in which the high refractive index pattern PT is not applied (Unapplied) and the cases in which the high refractive index pattern PT is applied (\textcircled{1} to \textcircled{4}).

Referring to FIGS. 13A and 13B, it can be seen that the light efficiency decreases as the viewing angle increases. It can be seen that when the first high refractive index pattern PT1 of FIG. 8 is applied (embodiments 1 (\textcircled{1}) to 4 (\textcircled{4})), the light efficiencies at a viewing angle of about 45 degrees are higher than the corresponding light efficiency when the first high refractive index pattern PT1 is not applied (the comparative example). Accordingly, it can be seen that the first high refractive index pattern PT1 is capable of increasing light efficiency at a side surface having a viewing angle of about 45 degrees.

Referring to FIGS. 8, 13A, and 13B, embodiment 3 (\textcircled{3}) has the highest light efficiency of 44.1% at a viewing angle of 45.5 degrees. It can be seen that the light efficiency at a viewing angle of 45.5 degrees is increased from 40.7% to 44.1% by about 3.4% when compared to that in the comparative example. It can be seen that when embodiment 2 (\textcircled{2}) is compared with embodiment 1 (\textcircled{1}), the separation distance is increased from 5 μm to 7 μm and the light efficiency at a viewing angle of 45.5 degrees is increased from 41.2% to 42.8%. At a viewing angle of 15.5 degrees, the light efficiency is decreased from 96.5% to 95.2%. At a viewing angle of 30.5 degrees, the light efficiency is decreased from 72.2% to 71.4%.

It can be seen that as the separation distance increases, the viewing angle at which the light efficiency increases is increased. In an embodiment, for example, referring to embodiments 1 (\textcircled{1}) and 2 (\textcircled{2}), it can be seen that when the separation distance is increased, the light efficiencies at viewing angles of 15.5 degrees and 30.5 degrees are decreased whereas the light efficiencies at viewing angles of 45.5 degrees and 60.5 degrees are increased.

When embodiment 3 (\textcircled{3}) is compared with embodiment 2 (\textcircled{2}), the thickness is increased from 2.2 μm to 4 μm, and the side angle is decreased from 90 degrees to 79 degrees. In this case, the light efficiency at a viewing angle of 45.5 degrees is increased from 42.8% to 44.1%. When embodiment 4 (\textcircled{4}) is compared with embodiment 3 (\textcircled{3}), the separation distance is increased from 7 μm to 8 μm, and the side angle is increased from 79 degrees to 90 degrees. In this case, the light efficiency at a viewing angle of 45.5 degrees is slightly decreased from 44.1% to 44%. It can be seen that in embodiments 2 (\textcircled{2}) to 4 (\textcircled{4}), the light efficiencies at viewing angles of 0.5 degrees and 15.5 degrees do not change much at all.

Table 2 below shows light efficiencies depending on viewing angles that are obtained by carrying out simulation while changing the thickness TH1, the separation distance CD, and the side angle θ of the high refractive index pattern PT of FIG. 8. More specifically, Table 2 below shows simulation results of light efficiencies of the display device depending on viewing angles when the second high refractive index pattern PT2 (refer to FIG. 8) covering the second emissive region LA2 (refer to FIG. 8) for emitting green light is applied.

In the comparative example, the second high refractive index pattern PT2 (refer to FIG. 8) is not applied. In embodiment 1 (\textcircled{1}), the second high refractive index pattern PT2 (refer to FIG. 8) has a thickness TH1 of 2.2 μm, a separation distance CD of 8.25 μm, and a side angle θ of 90 degrees. In embodiment 2 (\textcircled{2}), the second high refractive index pattern PT2 (refer to FIG. 8) has a thickness TH1 of 3 μm, a separation distance CD of 8.25 μm, and a side angle θ of 90 degrees. In embodiment 3 (\textcircled{3}), the second high refractive index pattern PT2 (refer to FIG. 8) has a thickness TH1 of 4 μm, a separation distance CD of 8.25 μm, and a side angle θ of 90 degrees. In embodiment 4 (\textcircled{4}), the second high refractive index pattern PT2 (refer to FIG. 8) has a thickness TH1 of 4 μm, a separation distance CD of 8.25 μm, and a side angle θ of 70 degrees. In embodiment 5 (\textcircled{5}), the second high refractive index pattern PT2 (refer to FIG. 8) has a thickness TH1 of 9.5 μm, a separation distance CD of 8.25 μm, and a side angle θ of 83 degrees.

TABLE 2

| | | Comparative | Embodiment | Embodiment | Embodiment | Embodiment | Embodiment |
|---|---|---|---|---|---|---|---|
| | | example | 1 (\textcircled{1}) | 2 (\textcircled{2}) | 3 (\textcircled{3}) | 4 (\textcircled{4}) | 5 (\textcircled{5}) |
| Thickness (μm) | | — | 2.2 | 3 | 4 | 4 | 9.5 |
| Separation | | — | 8.25 | 8.25 | 8.25 | 8.25 | 8.25 |
| distance (μm) | | | | | | | |
| Side angle | | — | 90 | 90 | 90 | 70 | 83 |
| (degree) | | | | | | | |
| Viewing | 0.5 | 100.0% | 100.5% | 100.7% | 100.4% | 100.4% | 100.0% |
| angle | 15.5 | 90.6% | 91.4% | 91.3% | 91.2% | 91.2% | 93.6% |
| (degree) | 30.5 | 67.4% | 68.7% | 69.0% | 69.6% | 69.4% | 79.4% |
| | 45.5 | 41.1% | 44.0% | 44.8% | 46.0% | 46.7% | 48.1% |
| | 60.5 | 24.3% | 26.8% | 27.1% | 27.4% | 27.1% | 23.8% |

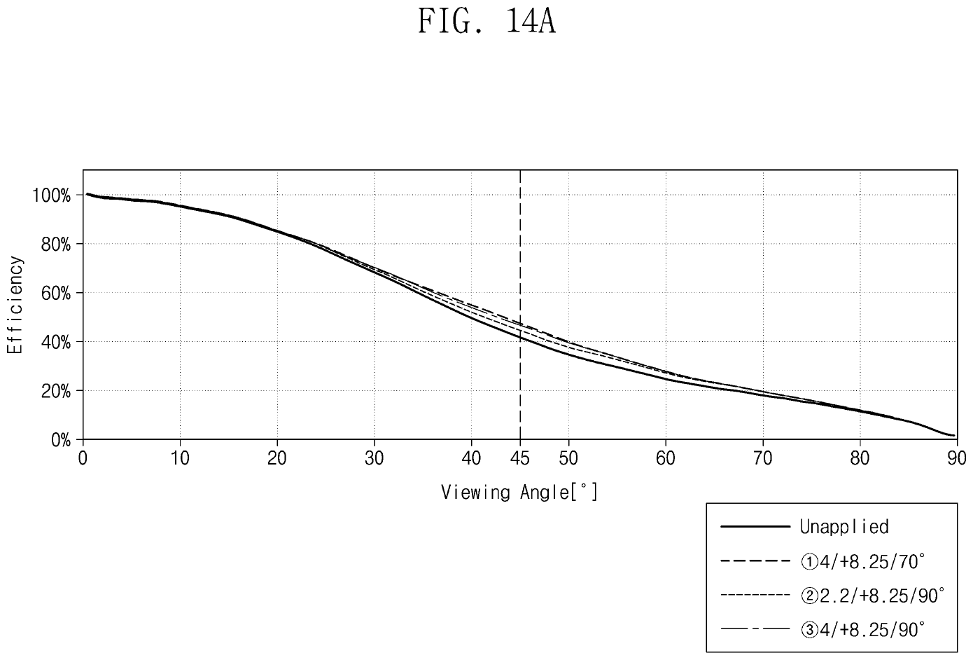

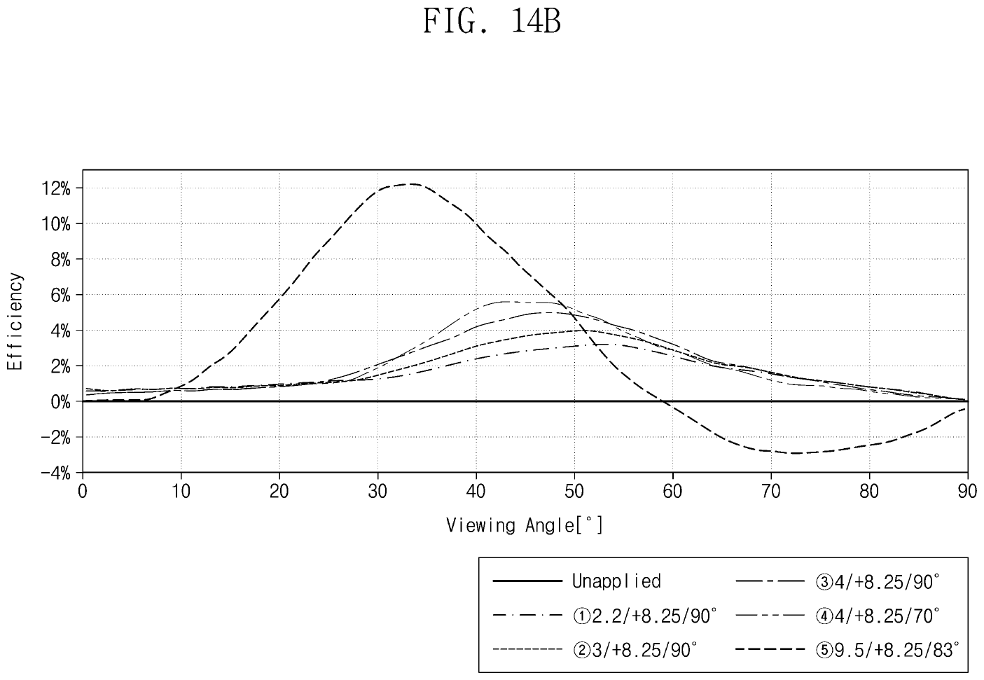

FIGS. 14A and 14B are views illustrating light efficiency depending on a viewing angle according to embodiments of the present disclosure. FIGS. 14A and 14B are graphs depicting the values in Table 2 above. FIG. 14B is a graph depicting differences in efficiency between the case in which the high refractive index pattern PT is not applied (Unapplied) and the cases in which the high refractive index pattern PT is applied (\textcircled{1} to \textcircled{5}).

Referring to FIGS. 14A and 14B, it can be seen that the light efficiency decreases as the viewing angle increases. It can be seen that when the second high refractive index pattern PT2 of FIG. 8 is applied (embodiments 1 (\textcircled{1}) to 5 (\textcircled{5})), the light efficiencies at a viewing angle of about 45 degrees are higher than the corresponding light efficiency when the second high refractive index pattern PT2 is not applied (the comparative example). Accordingly, it can be seen that the second high refractive index pattern PT2 is capable of increasing light efficiency at a side surface having a viewing angle of about 45 degrees.

Referring to FIGS. 8, 14A, and 14B, embodiment 5 (\textcircled{5}) has the highest light efficiency of 48.1% at a viewing angle of 45.5 degrees. The thickness TH1 of the second high refractive index pattern PT2 in embodiment 5 (\textcircled{5}) is 9.5 μm that is greater than those in embodiments 1 (\textcircled{1}) to 4 (\textcircled{4}). In this case, the viewing angle corresponding to the maximum value of the graph may be about 32 degrees and may be smaller than those in embodiments 1 (\textcircled{1}) to 4 (\textcircled{4}).

Referring to the graph of embodiments 1 (\textcircled{1}) to 5 (\textcircled{5}), it can be seen that as the thickness TH1 of the second high refractive index pattern PT2 is increased, the graph is shifted in the left direction in which the viewing angle is decreased. In this case, the separation distance CD may be increased such that the viewing angle corresponding to the maximum value of the graph is about 45 degrees. When the separation distance CD is increased, the viewing angle may be increased as described with reference to FIGS. 9 and 10A. That is, when the thickness TH1 of the high refractive index pattern PT is increased, the separation distance CD may be increased such that the viewing angle corresponding to the maximum value of the graph is about degrees.

However, as mentioned above, when the thickness TH1 of the second high refractive index pattern PT2 exceeds 5 μm, it may be difficult to implement the second high refractive index pattern PT2 in a process. Except for embodiment 5 (\textcircled{5}), embodiment 4 (\textcircled{4}) has the highest light efficiency of 46.7% at a viewing angle of 45.5 degrees. The light efficiency at a viewing angle of 45.5 degrees may be increased from 41.1% to 46.7% by about 5.6% when compared to that in the comparative example.

Referring to embodiments 1 (\textcircled{1}) to 3 (\textcircled{3}), it can be seen that only the thickness is increased to 2.2 μm, 3 μm, and 4 μm while the separation distance and the side angle are maintained at 8.25 μm and 90 degrees, respectively. In this case, it can be seen that the light efficiency at a viewing angle of 45.5 degrees is increased to 44%, 44.8%, and 46.8%. Considering this, it can be seen that as the thickness TH1 of the second high refractive index pattern PT2 is increased, the light efficiency at a viewing angle of 45.5 degrees, which is the light efficiency at the side surface, is increased.

When embodiment 4 (\textcircled{4}) is compared with embodiment 3 (\textcircled{3}), only the side angle may be decreased from 90 degrees to 70 degrees while the thickness and the separation distance are maintained at 4 μm and 8.25 μm, respectively. In this case, it can be seen that the light efficiency at a viewing angle of 45.5 degrees is increased to from 46% to 46.7%. As described above, it can be seen that the light efficiency at a viewing angle of 45.5 degrees is increased as the side angle is decreased.

Referring to Table 1 and FIGS. 8 and 13B, the separation distance CD of the first high refractive index pattern PT1 when the light efficiency at a viewing angle of 45.5 degrees is highest is 7 μm (embodiment 3 (\textcircled{3})). Referring to Table 2 and FIGS. 8 and 14B, the separation distance CD of the second high refractive index pattern PT2 when the light efficiency at a viewing angle of 45.5 degrees is highest is 8.25 μm (embodiment 4 (\textcircled{4})). That is, the separation distance CD of the second high refractive index pattern PT2 may be greater than the separation distance CD of the first high refractive index pattern PT1.

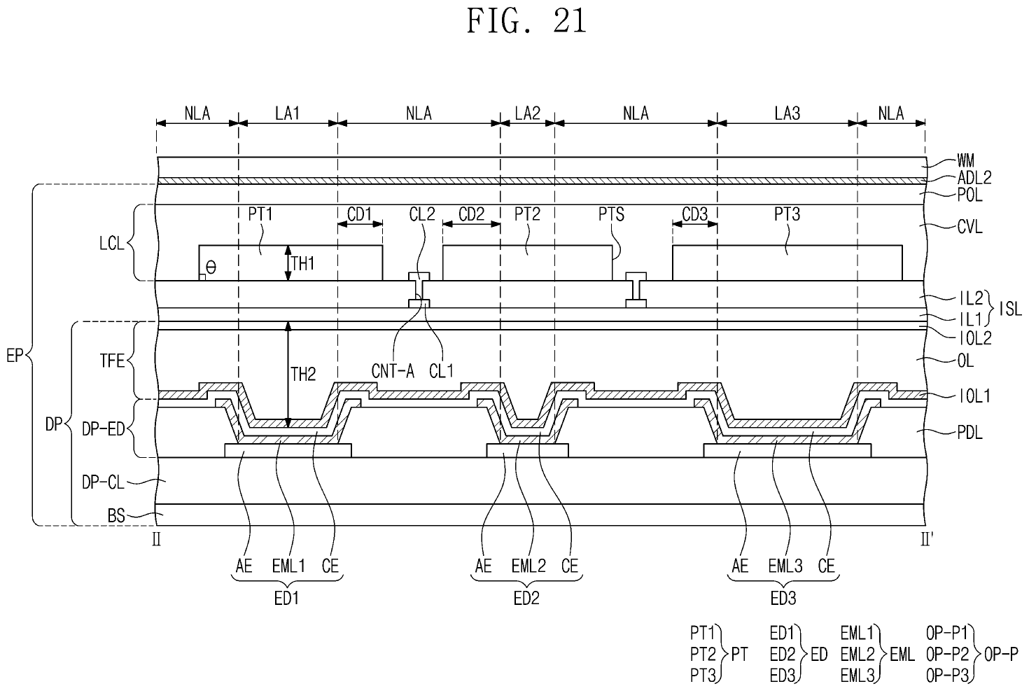

Considering this, the separation distances CD of the first and second high refractive index patterns PT1 and PT2 may differ from each other depending on which emissive regions LA1 and LA2 are covered by the high refractive patterns PT1 and PT2. In an embodiment, for example, the separation distance CD of the second high refractive index pattern PT2 covering the second emissive region LA2 for emitting green light may be greater than the separation distance CD of the first high refractive index pattern PT1 covering the first emissive region LA1 for emitting red light. Description thereabout will be given below with reference to FIG. 21.

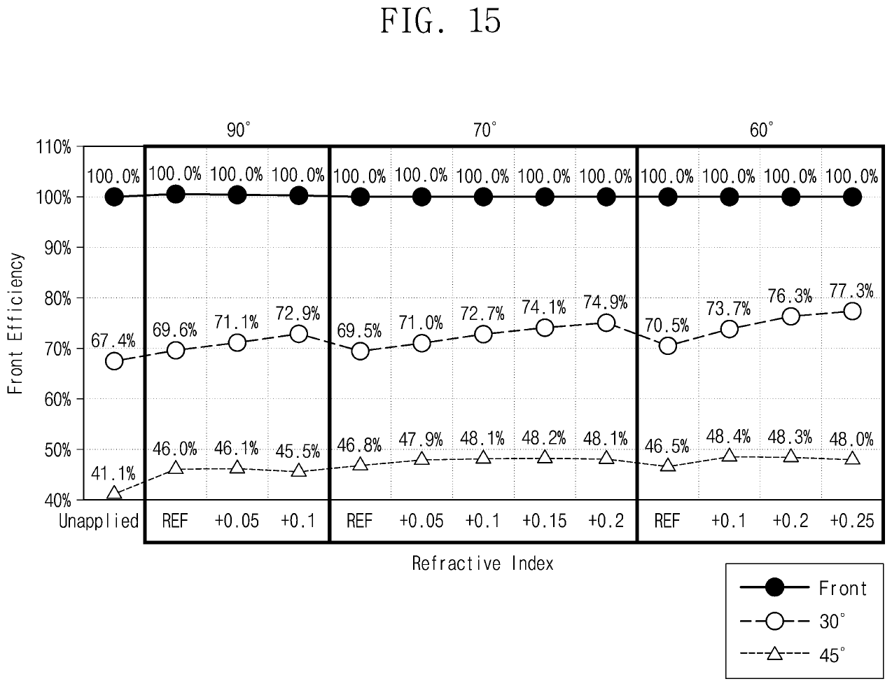

FIG. 15 is a graph depicting light efficiency depending on a side angle and a refractive index difference of the display device according to an embodiment of the present disclosure. More specifically, FIG. 15 is a graph depicting front efficiency, 30-degree efficiency, and 45-degree efficiency obtained by carrying out simulation while changing the side angle θ and a difference in refractive index between the low refractive index layer CVL and the high refractive index pattern PT (hereinafter, referred to as the refractive index difference) in a state in which the thickness TH1 and the separation distance CD of the second high refractive index pattern PT2 covering the second emissive region LA2 for emitting green light are maintained at 4 μm and 8.25 μm, respectively. As indicated by the thick line in FIG. 15, the simulation is performed on the cases where the side angle θ is 90 degrees, 70 degrees, and 60 degrees.

In FIG. 15, comparative examples REF may all mean the case in which the refractive index of the high refractive index pattern PT of FIG. 8 is about 1.623, the refractive index of the low refractive index layer CVL is 1.5, and the refractive index difference is 0.123. Hereinafter, when the refractive index difference is expressed as +0.05, this means that the refractive index difference is 0.173 that is greater than corresponding refractive index difference in the comparative example REF by 0.05. When the refractive index difference is expressed as +0.1, this means that the refractive index difference is 0.223 that is greater than corresponding refractive index difference in the comparative example REF by 0.1. When the refractive index difference is expressed as +0.15, this means that the refractive index difference is 0.273 that is greater than corresponding refractive index difference in the comparative example REF by 0.15. When the refractive index difference is expressed as +0.2, this means that the refractive index difference is 0.323 that is greater than corresponding refractive index difference in the comparative example REF by 0.2. When the refractive index difference is expressed as +0.25, this means that the refractive index difference is 0.373 that is greater than corresponding refractive index difference in the comparative example REF by 0.25.

Referring to FIGS. 8 and 15, when the high refractive index pattern PT is not applied (Unapplied), the efficiency at a viewing angle of 30 degrees is 67.4%, and the efficiency at a viewing angle of 45 degrees is 41.1%. These values are minimum values of the efficiencies at viewing angles of 30 degrees and 45 degrees, and it can be seen that when the high refractive index pattern PT is applied, the efficiencies at viewing angles of 30 degrees and 45 degrees are increased.

When the side angle θ is 90 degrees, the efficiency at a viewing angle of 30 degrees in the comparative example REF is 69.6%, and the efficiency at a viewing angle of 45 degrees in the comparative example REF is 46.0%. In the case in which the refractive index difference is increased by +0.05 and +0.1 when compared to that in the comparative example REF, the efficiency at a viewing angle of 30 degrees is increased to 71.1% and 72.9%. However, the efficiency at a viewing angle of 45 degrees is increased to 46.1% in the case in which the refractive index difference is increased by +0.05 when compared to that in the comparative example REF, whereas the efficiency at a viewing angle of 45 degrees is decreased to 45.5% in the case in which the refractive index difference is increased by +0.1 when compared to that in the comparative example REF. The efficiency at a viewing angle of 45 degrees has the highest value of 46.1% in the case in which the refractive index difference is increased by +0.05 when compared to that in the comparative example REF.

When the side angle θ is 70 degrees, the efficiency at a viewing angle of 30 degrees in the comparative example REF is 69.5%, and the efficiency at a viewing angle of 45 degrees in the comparative example REF is 46.8%. It can be seen that the efficiency at a viewing angle of 45 degrees is increased from 46.0% to 46.8% as compared with when the side angle θ is 90 degrees. It can be seen that in the case in which the refractive index difference is increased by +0.05, +0.1, +0.15, and +0.2 when compared to that in the comparative example REF, the efficiency at a viewing angle of 30 degrees is increased to 71.0%, 72.7%, 74.1%, and 74.9%. It can be seen that in the case in which the refractive index difference is increased by +0.05, +0.1, and +0.15 when compared to that in the comparative example REF, the efficiency at a viewing angle of 45 degrees is increased to 47.9%, 48.1%, and 48.2%. It can be seen that in the case in which the refractive index difference is increased by +0.2 when compared to that in the comparative example REF, the efficiency at a viewing angle of 45 degrees is decreased to 48.1% as compared with when the refractive index difference is greater than corresponding refractive index difference in the comparative example REF by +0.15.

When the side angle θ is 60 degrees, the efficiency at a viewing angle of 30 degrees in the comparative example REF is 70.5%, and the efficiency at a viewing angle of 45 degrees in the comparative example REF is 46.5%. It can be seen that the efficiency at a viewing angle of 45 degrees is slightly decreased to 46.5% as compared with when the side angle θ is 70 degrees. It can be seen that in the case in which the refractive index difference is increased by +0.1, +0.2, and +0.25 when compared to that in the comparative example REF, the efficiency at a viewing angle of 30 degrees is increased to 73.7%, 76.3%, and 77.3%. It can be seen that the efficiency at a viewing angle of 45 degrees is increased to 48.4% in the case in which the refractive index difference is increased by +0.1 when compared to that in the comparative example REF, whereas the efficiency at a viewing angle of 45 degrees is gradually decreased to 48.3% and 48.0% in the case in which the refractive index difference is increased by +0.2 and +0.25 when compared to that in the comparative example REF.

In the case in which the side angle is 90 degrees and the refractive index difference is increased by +0.05 when compared to that in the comparative example REF, the efficiency at a viewing angle of 30 degrees is 71.1%, and the efficiency at a viewing angle of 45 degrees is 46.1% (CASE 1). In the case in which the side angle is 70 degrees and the refractive index difference is increased by +0.15 when compared to that in the comparative example REF, the efficiency at a viewing angle of 30 degrees is 74.1%, and the efficiency at a viewing angle of 45 degrees is 48.2% (CASE 2). In the case in which the side angle is 60 degrees and the refractive index difference is increased by +0.2 when compared to that in the comparative example REF, the efficiency at a viewing angle of 30 degrees is 76.3%, and the efficiency at a viewing angle of 45 degrees is 48.3% (CASE 3).

Referring to CASE 1 to CASE 3, it can be seen that the efficiencies at viewing angles of 30 degrees and 45 degrees are additionally improved by decreasing the side angle θ and increasing the refractive index difference. In an embodiment, for example, when the side angle θ ranges from 60 degrees to 70 degrees and the difference in refractive index between the high refractive index pattern PT and the low refractive index layer CVL ranges from 0.25 to 0.35 as in CASE 2 and CASE 3, the efficiencies at viewing angles of 30 degrees and 45 degrees may be increased.

Table 3 below shows light efficiencies depending on viewing angles that are obtained by carrying out simulation while changing the difference in refractive index between the second high refractive index pattern PT2 and the low refractive index layer CVL of FIG. 8. In all cases of Table 3, only the refractive index difference is changed while the thickness TH1, the separation distance CD, and the side angle θ of the second high refractive index pattern PT2 are maintained at 4 μm, 8.25 μm, and 90 degrees, respectively.

TABLE 3

| | | Comparative | Embodiment | Embodiment | Embodiment | Embodiment |
|---|---|---|---|---|---|---|
| | | example | 1 (\textcircled{1}) | 2 (\textcircled{2}) | 3 (\textcircled{3}) | 4 (\textcircled{4}) |
| Refractive index | | 0.123 | 0.173(+0.05) | 0.223(+0.1) | 0.273(+0.15) | 0.323(+0.2) |
| difference | | | | | | |
| Thickness (μm) | | 4 | 4 | 4 | 4 | 4 |
| Separation | | 8.25 | 8.25 | 8.25 | 8.25 | 8.25 |
| distance (μm) | | | | | | |
| Side angle | | 90 | 90 | 90 | 90 | 90 |
| (degree) | | | | | | |
| Viewing | 0.5 | 100.4% | 100.0% | 100.2% | 100.2% | 99.8% |
| angle | 15.5 | 91.2% | 91.5% | 92.0% | 91.8% | 91.2% |
| (degree) | 30.5 | 69.6% | 71.1% | 71.0% | 70.3% | 69.7% |
| | 45.5 | 46.0% | 46.1% | 45.5% | 44.6% | 43.2% |
| | 60.5 | 27.4% | 27.4% | 27.6% | 26.5% | 24.9% |

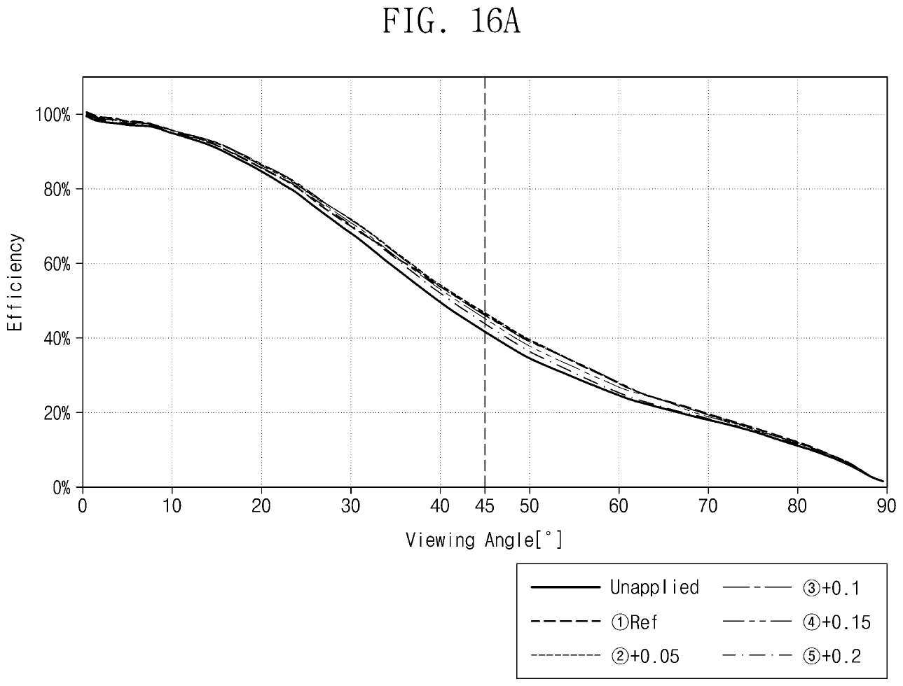

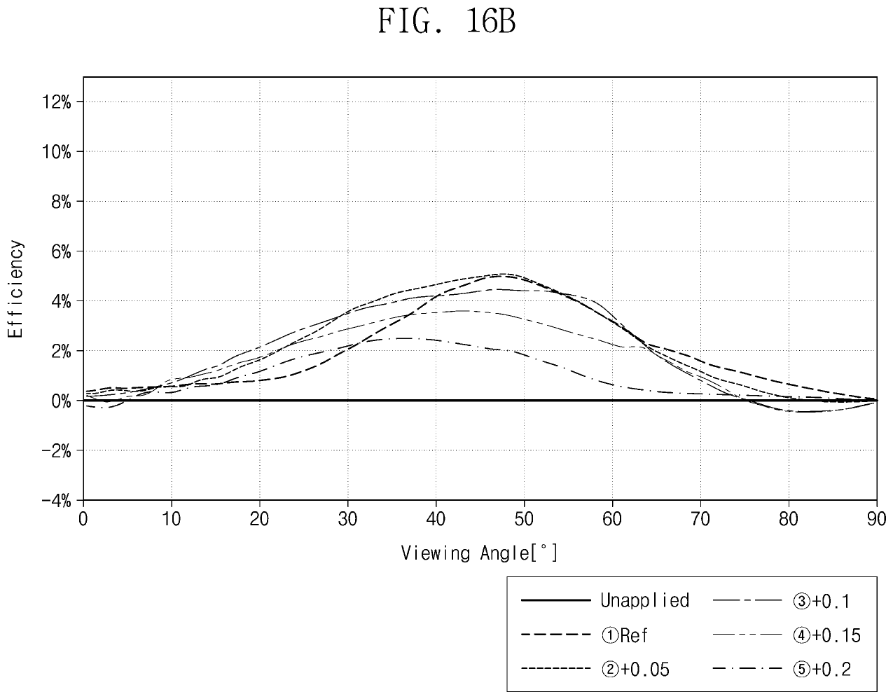

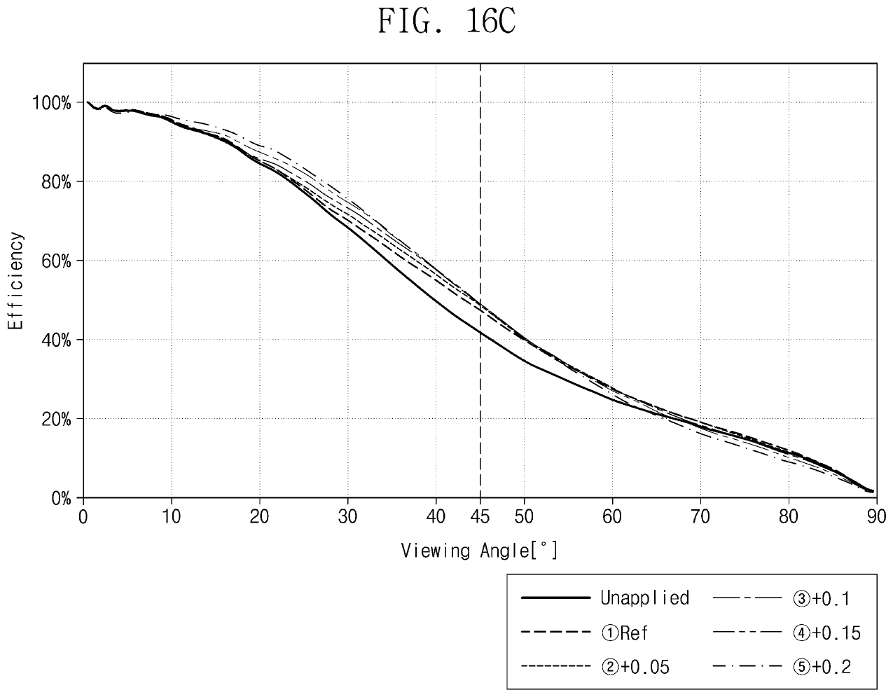

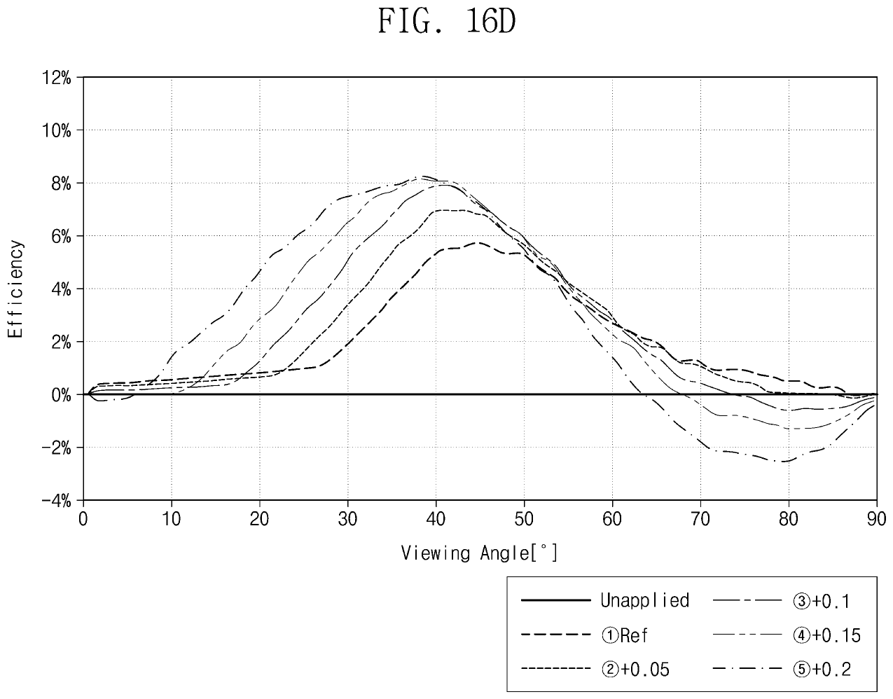

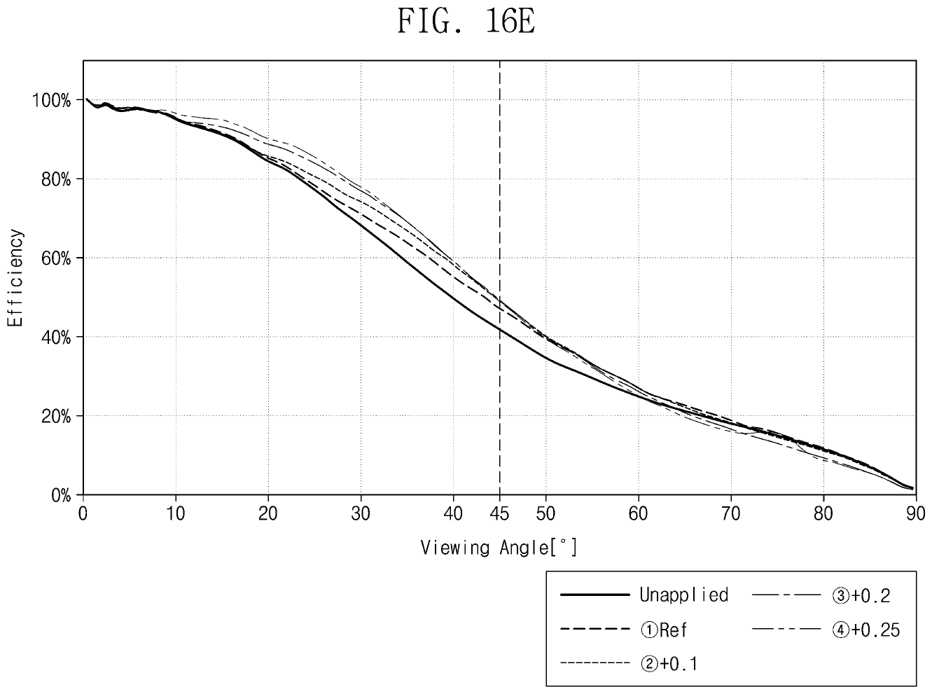

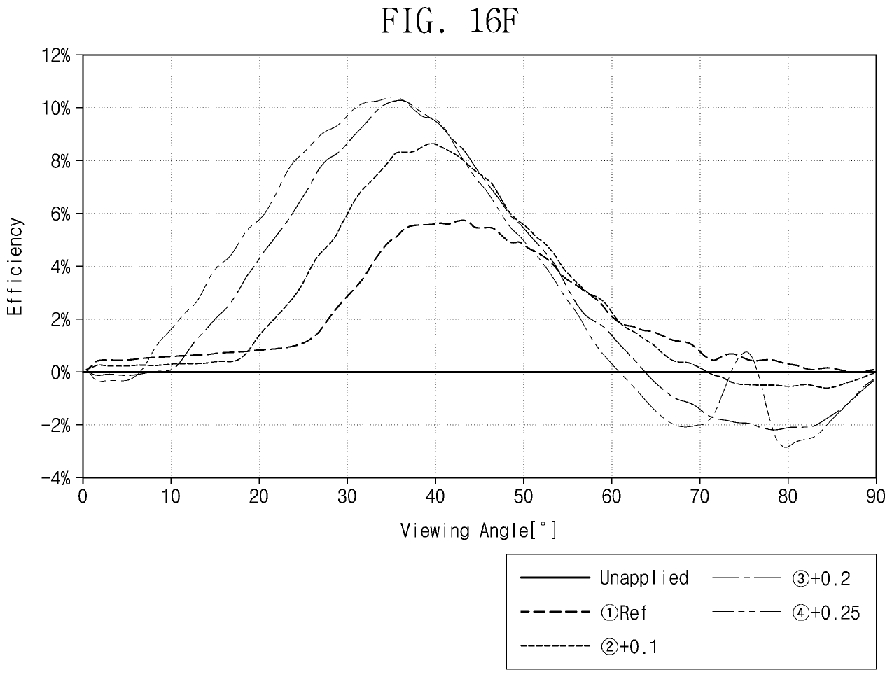

FIGS. 16A and 16B are graphs depicting light efficiency depending on a viewing angle of the display device when a refractive index difference is varied according to an embodiment of the present disclosure. FIGS. 16A and 16B are graphs depicting the values in Table 3 above. FIG. 16B is a graph depicting a difference in efficiency between when the second high refractive pattern PT2 is not applied (Unapplied) and when the second high refractive pattern PT2 is applied (REF and \textcircled{1} to \textcircled{4}).

Referring to Table 3 and FIGS. 16A and 16B, it can be seen that the efficiency at a viewing angle of 45 degrees is increased to 46.1% when the refractive index difference is increased to 0.173 (+0.05) (embodiment 1 (\textcircled{1})). However, it can be seen that when the refractive index difference exceeds 0.173 (+0.05) (embodiment 2 (\textcircled{2}) to embodiment 4 (\textcircled{4})), the efficiency at a viewing angle of 45 degrees is decreased as the refractive index difference is increased. This is because when the side angle θ is 90 degrees, light emitted from the light emitting element ED (refer to FIG. 8) fails to travel to the outside due to total reflection. Accordingly, it may be appropriate that the refractive index difference is 0.173 (+0.05) or less when the side angle θ is 90 degrees.

Table 4 below shows light efficiencies depending on viewing angles that are obtained by carrying out simulation while changing the difference in refractive index between the second high refractive index pattern PT2 and the low refractive index layer CVL of FIG. 8. In all cases of Table 4, only the refractive index difference is changed while the thickness TH1, the separation distance CD, and the side angle θ of the second high refractive index pattern PT2 are maintained at 4 μm, 8.25 μm, and 70 degrees, respectively. The side angle θ in Table 4 is decreased from 90 degrees to 70 degrees when compared to that in Table 3.

TABLE 4

| | | Comparative | Embodiment | Embodiment | Embodiment | Embodiment |
|---|---|---|---|---|---|---|
| | | example | 1 (\textcircled{1}) | 2 (\textcircled{2}) | 3 (\textcircled{3}) | 4 (\textcircled{4}) |
| Refractive index | | 0.123 | 0.173(+0.05) | 0.223(+0.1) | 0.273(+0.15) | 0.323(+0.2) |
| difference | | | | | | |
| Thickness (μm) | | 4 | 4 | 4 | 4 | 4 |
| Separation | | 8.25 | 8.25 | 8.25 | 8.25 | 8.25 |
| distance (μm) | | | | | | |
| Side angle | | 70 | 70 | 70 | 70 | 70 |
| (degree) | | | | | | |
| Viewing | 0.5 | 100.0% | 100.0% | 100.0% | 100.0% | 100.0% |
| angle | 15.5 | 91.4% | 91.2% | 91.0% | 92.1% | 93.5% |
| (degree) | 30.5 | 69.5% | 71.0% | 72.7% | 74.1% | 74.9% |
| | 45.5 | 46.8% | 47.9% | 48.1% | 48.2% | 48.1% |
| | 60.5 | 27.0% | 27.1% | 27.0% | 26.5% | 25.6% |

FIGS. 16C and 16D are graphs depicting light efficiency depending on a viewing angle of the display device when a refractive index difference is varied according to an embodiment of the present disclosure. FIGS. 16C and 16D are graphs depicting the values in Table 4 above. FIG. 16D is a graph depicting a difference in efficiency between when the second high refractive pattern PT2 is not applied (Unapplied) and when the second high refractive pattern PT2 is applied (REF and \textcircled{1} to \textcircled{4}).

Referring to Table 4 and FIGS. 16C and 16D, it can be seen that the efficiency at a viewing angle of 45 degrees is increased to 48.2% when the refractive index difference is increased to 0.273 (+0.15) (embodiment 3 (\textcircled{3})). However, it can be seen that when the refractive index difference exceeds 0.273 (+0.15) (embodiment 4 (\textcircled{4})), the efficiency at a viewing angle of 45 degrees is slightly decreased to 48.1%. To maximize the efficiency at a viewing angle of 45 degrees, it may be appropriate that the refractive index difference is about 0.273.

Referring to FIGS. 8 and 16D, it can be seen that as the refractive index difference is increased, the vertical-axis value of the graph corresponding to a difference in efficiency between when the high refractive index pattern PT is applied and when the high refractive index pattern PT is not applied (Unapplied) is increased at a viewing angle of 50 degrees or less. In addition, it can be seen that as the refractive index difference is increased, the viewing angle corresponding to the peak of the graph at which the difference in efficiency between when the high refractive index pattern PT is applied and when the high refractive index pattern PT is not applied (Unapplied) is largest is decreased.

Table 5 below shows light efficiencies depending on viewing angles that are obtained by carrying out simulation while changing the difference in refractive index between the second high refractive index pattern PT2 and the low refractive index layer CVL of FIG. 8. In all cases of Table 5, only the refractive index difference is changed while the thickness TH1, the separation distance CD, and the side angle θ of the second high refractive index pattern PT2 are maintained at 4 μm, 8.25 μm, and 60 degrees, respectively. The side angle θ in Table 5 is decreased from 70 degrees to 60 degrees when compared to that in Table 4.

TABLE 5

| | | Comparative | Embodiment | Embodiment | Embodiment |
|---|---|---|---|---|---|
| | | example | 1 (\textcircled{1}) | 2 (\textcircled{2}) | 3 (\textcircled{3}) |
| Refractive index | | 0.123 | 0.223(+0.1) | 0.323(+0.2) | 0.373(+0.25) |
| difference | | | | | |
| Thickness (μm) | | 4 | 4 | 4 | 4 |
| Separation | | 8.25 | 8.25 | 8.25 | 8.25 |
| distance (μm) | | | | | |
| Side angle (degree) | | 60 | 60 | 60 | 60 |
| Viewing | 0.5 | 100.0% | 100.0% | 100.0% | 100.0% |
| angle | 15.5 | 91.4% | 91.0% | 92.8% | 94.7% |
| (degree) | 30.5 | 70.5% | 73.7% | 76.3% | 77.3% |
| | 45.5 | 46.5% | 48.4% | 48.3% | 48.0% |
| | 60.5 | 26.3% | 26.4% | 25.5% | 24.5% |

FIGS. 16E and 16F are graphs depicting light efficiency depending on a viewing angle of the display device when a refractive index difference is varied according to an embodiment of the present disclosure. FIGS. 16E and 16F are graphs depicting the values in Table 5 above. FIG. 16F is a graph depicting a difference in efficiency between when the second high refractive pattern PT2 is not applied (Unapplied) and when the second high refractive pattern PT2 is applied (REF and \textcircled{1} to \textcircled{3}).

Referring to Table 5 and FIGS. 16E and 16F, it can be seen that the efficiency at a viewing angle of 45 degrees is increased to 48.4% when the refractive index difference is increased to 0.223 (+0.1) (embodiment 1 (\textcircled{1})). However, it can be seen that when the refractive index difference exceeds 0.223 (+0.1), the efficiency at a viewing angle of 45 degrees is slightly decreased to 48.3% and 48.0% as in embodiment 2 (\textcircled{2}) and embodiment 3 (\textcircled{3}). To maximize the efficiency at a viewing angle of 45 degrees, it may be appropriate that the refractive index difference is about 0.223.

Referring to FIGS. 8 and 16F, it can be seen that as the refractive index difference is increased, the vertical-axis value of the graph corresponding to a difference in efficiency between when the high refractive index pattern PT is applied and when the high refractive index pattern PT is not applied (Unapplied) is increased at a viewing angle of 50 degrees or less. In addition, it can be seen that as the refractive index difference is increased, the viewing angle corresponding to the peak of the graph at which the difference in efficiency between when the high refractive index pattern PT is applied and when the high refractive index pattern PT is not applied (Unapplied) is largest is decreased.

Referring to FIGS. 8, 16D, and 16F, it can be seen that the viewing angle corresponding to the peak of the graph is decreased when the difference in refractive index between the second high refractive index pattern PT2 and the low refractive index layer CVL is increased. In this case, the separation distance CD may be increased to adjust the viewing angle corresponding to the peak of the graph to about 45 degrees. That is, the separation distance CD may be adjusted depending on the refractive index difference. The separation distance CD may be increased as the difference in refractive index between the second high refractive index pattern PT2 and the low refractive index layer CVL is increased.

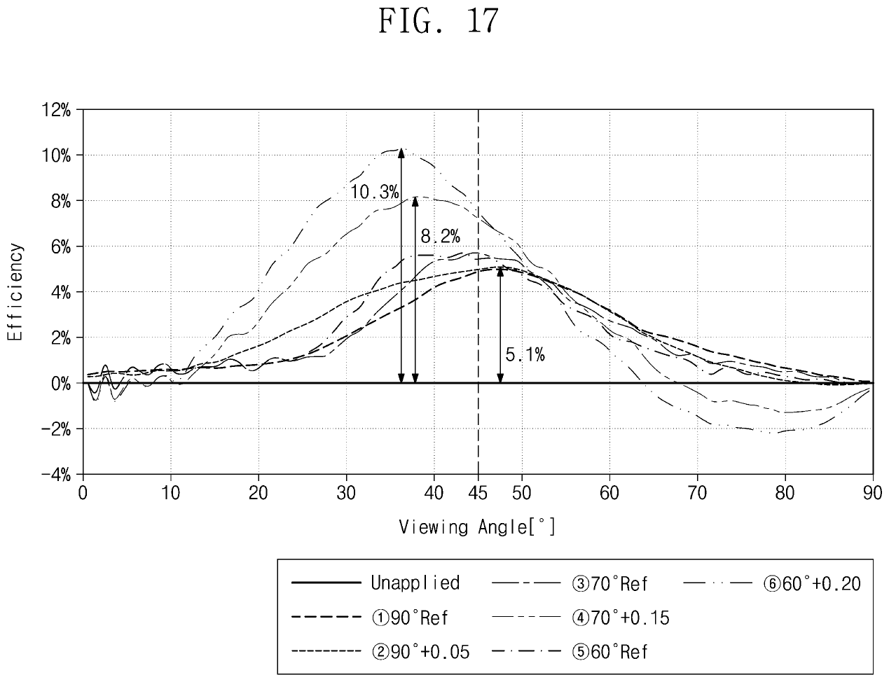

FIG. 17 is a graph depicting light efficiency depending on a viewing angle of the display device according to an embodiment of the present disclosure. Portions of the graphs of FIGS. 16B, 16D, and 16F are illustrated on one graph of FIG. 17. The graphs of FIG. 16B that correspond to REF and +0.05 are illustrated as 90-degree REF (graph 1) and 90-degree+0.05 (graph 2) in FIG. 17. The graphs of FIG. 16D that correspond to REF and +0.15 are illustrated as 70-degree REF (graph 3) and 70-degree+0.15 (graph 4) in FIG. 17. The graphs of FIG. 16F that correspond to REF and +0.2 are illustrated as 60-degree REF (graph 5) and 60-degree+0.20 (graph 6) in FIG. 17.

The efficiency at a viewing angle of 45 degrees in graph 2 is higher than the efficiency at a viewing angle of 45 degrees in graph 1, the efficiency at a viewing angle of 45 degrees in graph 4 is higher than the efficiency at a viewing angle of 45 degrees in graph 3, and the efficiency at a viewing angle of 45 degrees in graph 6 is higher than the efficiency at a viewing angle of 45 degrees in graph 5. That is, when the side angle θ is the same, the efficiency at a viewing angle of 45 degrees may be increased by increasing the refractive index difference.

Referring to graph 2, when the difference in efficiency between when the second high refractive index pattern PT2 is applied and when the second high refractive index pattern PT2 is not applied (Unapplied) is largest, the efficiency difference is 5.1%, and in this case, the viewing angle is about 47 degrees. Referring to graph 4, when the difference in efficiency between when the second high refractive index pattern PT2 is applied and when the second high refractive index pattern PT2 is not applied (Unapplied) is largest, the efficiency difference is 8.2%, and in this case, the viewing angle is about 38 degrees. Referring to graph 6, when the difference in efficiency between when the second high refractive index pattern PT2 is applied and when the second high refractive index pattern PT2 is not applied (Unapplied) is largest, the efficiency difference is 10.3%, and in this case, the viewing angle is about 36 degrees.

When the side angle θ is decreased, the maximum value of the efficiency difference is increased, and the viewing angle is decreased. In this case, to adjust the viewing angle corresponding to the maximum value of the efficiency difference to 45 degrees, the separation distance CD of FIG. 8 may be adjusted. The viewing angle corresponding to the maximum value of the efficiency difference may be adjusted to 45 degrees by increasing the separation distance CD when the side angle θ is decreased. For example, in the case of graph 6, the viewing angle corresponding to the maximum value of the efficiency difference may be increased by increasing the separation distance CD.

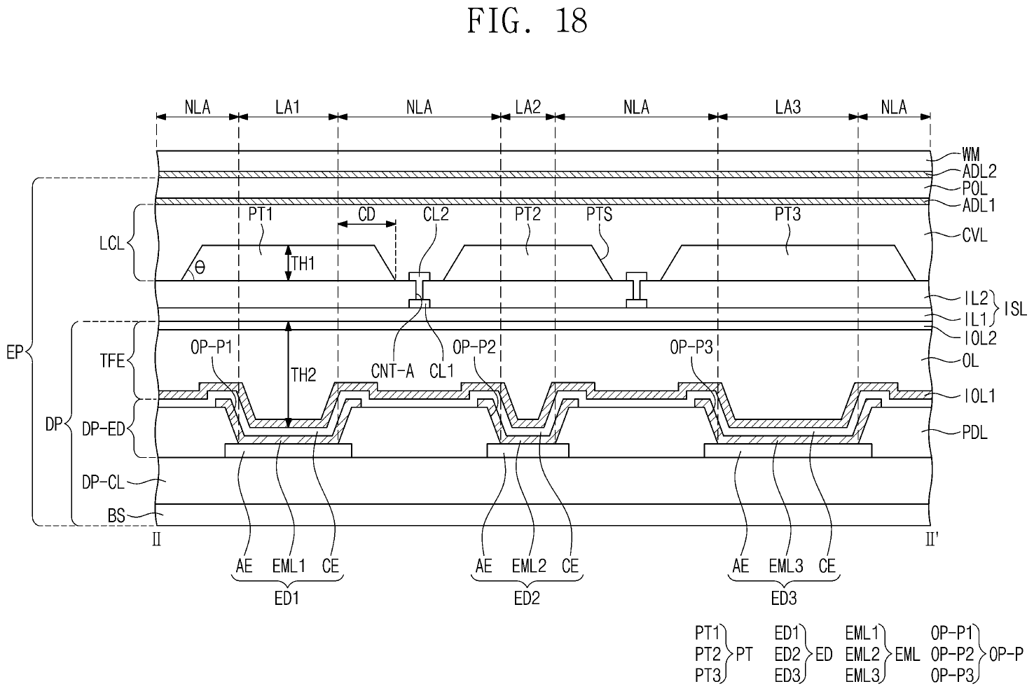

FIG. 18 is a sectional view of the display device taken along line II-II′ of FIG. 7 according to another embodiment of the present disclosure. The configuration of FIG. 18 is the same as the configuration described with reference to FIG. 8 except for the side angle θ, and therefore description thereabout will be omitted.

Referring to FIG. 18, the side angle θ formed by the side surface PTS of the high refractive index pattern PT with respect to the upper surface of the second sensing insulation layer IL2 may range from 60 degrees to 90 degrees. In this case, the high refractive index pattern PT may have a trapezoidal shape in which a lower side is larger than an upper side in a plan view.

As the high refractive index pattern PT has a trapezoidal cross-section, a large amount of light may be refracted through the side surface PTS. That is, when the high refractive index pattern PT has a trapezoidal cross-section, a larger amount light may be refracted at the side surface PTS than when the high refractive index pattern PT has a rectangular cross-section.

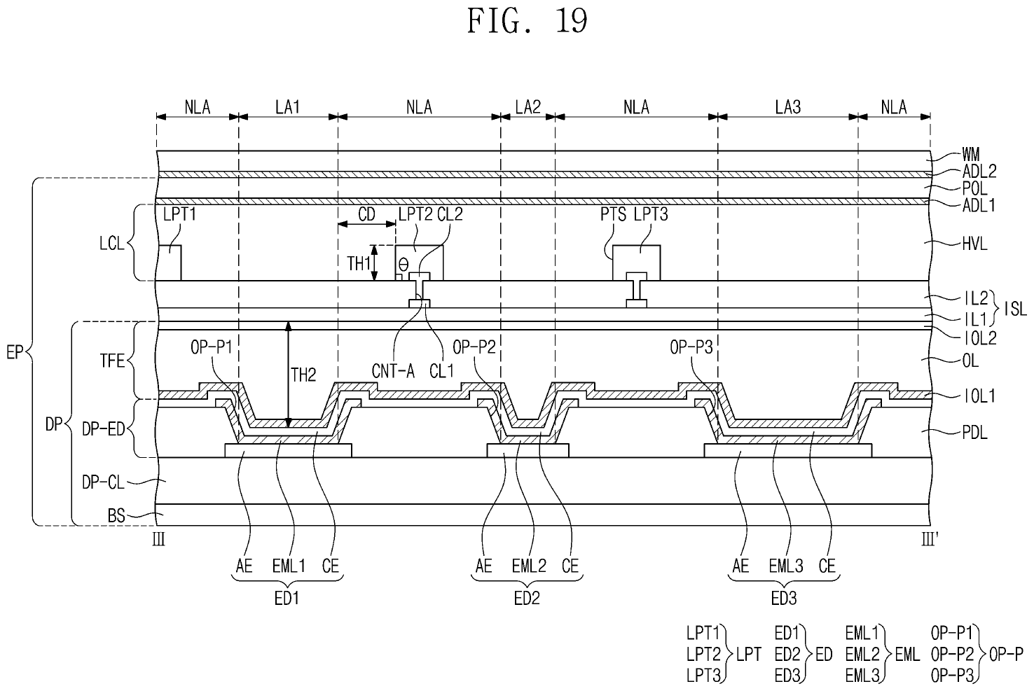

FIG. 19 is a sectional view of the display device according to an embodiment of the present disclosure. Hereinafter, descriptions of components identical to the components described with reference to FIG. 8 will be omitted.

Referring to FIG. 19, a light control layer LCL may be disposed on the input sensing unit ISL. The light control layer LCL may include a low refractive index pattern LPT and a high refractive index layer HVL. The low refractive index pattern LPT may be disposed on the second sensing insulation layer IL2. The low refractive index pattern LPT may cover the second conductive layer CL2. The low refractive index pattern LPT may overlap the non-emissive region NLA. The low refractive index pattern LPT may include first to third low refractive index patterns LPT1, LPT2, and LPT3. The first low refractive index pattern LPT1 may be disposed adjacent to the first emissive region LA1, the second low refractive index pattern LPT2 may be disposed adjacent to the second emissive region LA2, and the third low refractive index pattern LPT3 may be disposed adjacent to the third emissive region LA3.

The high refractive index layer HVL may be disposed on the low refractive index pattern LPT and may cover the low refractive index pattern LPT. The high refractive index layer HVL may fill spaces between the first to third low refractive index patterns LPT1, LPT2, and LPT3. The high refractive index layer HVL may have a flat upper surface and may overlap the emissive region LA and the non-emissive region NLA.

The low refractive index pattern LPT and the high refractive index layer HVL may have different refractive indexes. The low refractive index pattern LPT may have a first refractive index, and the high refractive index layer HVL may have a second refractive index greater than the first refractive index. Here, the first refractive index may range from 1.3 to 1.5. The second refractive index may range from 1.5 to 1.8. Specifically, for light in a wavelength range of 550 nm to 660 nm, the first refractive index may range from 1.3 to 1.5, and the second refractive index may range from 1.5 to 1.8.

The separation distance CD by which a side surface PTS of the low refractive index pattern LPT is spaced apart from one side surface of the emissive region LA closest to the side surface PTS may range from 6 μm to 9 μm. When the separation distance CD is less than 6 μm, the viewing angle of light refracted at the side surface PTS and output to the outside may be decreased. When the separation distance CD exceeds 9 μm, the viewing angle of light refracted at the side surface PTS and output to the outside may be decreased. Accordingly, to increase the efficiency of light that is output to the curved surface SS of the window WM of FIG. 3 and that has a viewing angle of about 45 degrees, it may be appropriate that the separation distance CD ranges from 6 μm to 9 μm.

The low refractive index pattern LPT may have a thickness of 2 μm to 5 μm. When the thickness of the low refractive index pattern LPT is less than 2 μm, the area of the side surface PTS may be decreased, and therefore the amount of light output through the side surface PTS may be reduced. When the thickness of the low refractive index pattern LPT exceeds 5 μm, it may be difficult to implement the low refractive index pattern LPT in a process. For example, a deep portion of the low refractive index pattern LPT may not be sufficiently cured by exposure in a general photolithography process. In addition, process accuracy may be reduced, which may lead to a reduction in process yield.

A side angle θ formed by the side surface PTS of the low refractive index pattern LPT with respect to the upper surface of the second sensing insulation layer IL2 may range from 90 degrees to 120 degrees. When the side angle θ exceeds 120 degrees, light refracted through the side surface PTS may be refracted to an excessively high degree. When the side angle θ is less than 90 degrees, light refracted through the side surface PTS may be refracted to an excessively small degree. Accordingly, it may be appropriate that the side angle θ ranges from 90 degrees to 120 degrees such that the viewing angle of light refracted through the side surface PTS is about 45 degrees.

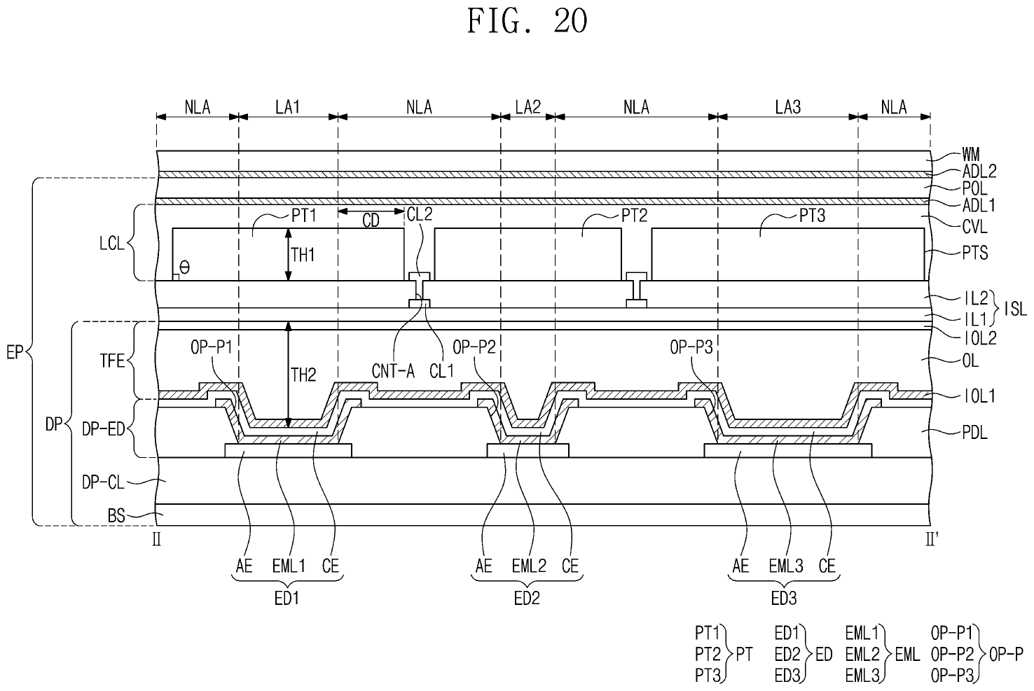

FIG. 20 is a sectional view of the display device taken along line II-II′ of FIG. 7 according to still another embodiment of the present disclosure. The configuration of FIG. 20 is the same as the configuration of FIG. 8 except for the thickness TH1, and description of the same configuration will be omitted.

Referring to FIG. 20, the high refractive index PT may have a thickness TH1 of 10 μm or more. When the thickness TH1 of the high refractive index pattern PT is increased, light efficiency may be increased at a viewing angle of about 45 degrees. However, when the thickness of the high refractive index pattern PT exceeds μm, it may be difficult to implement the high refractive index pattern PT using a general photolithography process.

To form the high refractive index pattern PT, a high refractive index layer having a thickness of 10 μm or more and covering the second sensing insulation layer IL2 may be formed. An inorganic film, which is a metal such as indium zinc oxide (“IZO”) or aluminum (Al), may be applied to the high refractive index layer. An inorganic pattern may be formed by etching the inorganic film in a shape corresponding to the shape of the high refractive index pattern PT. The high refractive index pattern PT may be formed by etching the high refractive index layer with the inorganic pattern as a mask. After the high refractive index pattern PT is formed, the inorganic pattern may be removed through wet etching. When the high refractive index pattern PT is formed as described above, process accuracy and process yield may not be reduced even though the thickness TH1 is 10 μm or more.

FIG. 21 is a sectional view of the display device taken along line II-II′ of FIG. 7 according to yet another embodiment of the present disclosure. The configuration of FIG. 21 is the same as the configuration of FIG. 8 except for first to third separation distances CD1 to CD3, and therefore description of the same configuration will be omitted.

Referring to FIG. 21, the first high refractive index pattern PT1 may cover the first emissive region LA1 for emitting red light. The second high refractive index pattern PT2 may cover the second emissive region LA2 for emitting green light. The third high refractive index pattern PT3 may cover the third emissive region LA3 for emitting blue light.

The side surface PTS of the first high refractive index pattern PT1 may be spaced apart from one side surface of the first emissive region LA1 closest to the side surface PTS by the first separation distance CD1 in the plan view. The side surface PTS of the second high refractive index pattern PT2 may be spaced apart from one side surface of the second emissive region LA2 closest to the side surface PTS by the second separation distance CD2. The side surface PTS of the third high refractive index pattern PT3 may be spaced apart from one side surface of the third emissive region LA3 closest to the side surface PTS by the third separation distance CD3. The first to third separation distances CD1 to CD3 may have different values. The first to third separation distances CD1 to CD3 may range from 6 μm to 9 μm.

The second separation distance CD2 may be greater than the first separation distance CD1 in the plan view. Referring to FIGS. 13B and 14B, the first separation distance CD1 when the efficiency at a viewing angle of 45 degrees is highest is 7 μm (refer to FIG. 13B), and the second separation distance CD2 when the efficiency at a viewing angle of 45 degrees is highest is 8.25 μm (refer to FIG. 14B). Accordingly, to increase the efficiency at a viewing angle of 45 degrees, it may be more appropriate that the second separation distance CD2 is greater than the first separation distance CD1.

The polarization unit POL may be directly disposed on the low refractive index layer CVL. An adhesive layer may not be disposed between the polarization unit POL and the low refractive index layer CVL. In this case, the low refractive index layer CVL may serve as an adhesive layer. The low refractive index layer CVL may include an adhesive material having a refractive index of about 1.3 to about 1.5.

According to the embodiments of the present disclosure, the display device may emit, through the high refractive index pattern and the low refractive index layer, light that is not output to the outside due to total reflection in the window, thereby effectively increasing light efficiency.

In addition, the interface between the high refractive index pattern and the low refractive index layer may be spaced apart from the emissive region by a predetermined distance, and thus the luminance of the side surface having a viewing angle of 45 degrees on average may be effectively increased.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display device comprising:
a display panel including a plurality of emissive regions and a non-emissive region adjacent to the plurality of emissive regions;
an input sensing unit disposed on the display panel, and including a sensing insulation layer disposed on the display panel and a conductive layer disposed on the sensing insulation layer, wherein the conductive layer overlaps the non-emissive region;
a light control layer disposed on the input sensing unit; and
a window disposed on the light control layer, and including a front surface and a curved surface curved from the front surface,
wherein the light control layer includes:
a high refractive index pattern disposed on the sensing insulation layer, covering each of the plurality of emissive regions in a plan view, and having a first refractive index; and
a low refractive index layer covering the high refractive index pattern and the conductive layer and overlapping the non-emissive region and the emissive region, wherein the low refractive index layer has a second refractive index smaller than the first refractive index, and
wherein a separation distance by which one side surface of the high refractive index pattern is spaced apart from one side surface of an emissive region closest to the one side surface of the high refractive index pattern among plurality of emissive regions ranges from 6 micrometers (μm) to 9 μm in the plan view.

2. The display device of claim 1, wherein the display panel includes:
a base layer;
a light emitting element disposed on the base layer and overlapping the emissive region; and
a thin film encapsulation layer disposed on the light emitting element and sealing the light emitting element, and
wherein the thin film encapsulation layer has a thickness of 10 μm to 11 μm.

3. The display device of claim 1, wherein the high refractive index pattern has a thickness of 2 μm to 5 μm.

4. The display device of claim 1, wherein a side angle formed by a side surface of the high refractive index pattern with respect to an upper surface of the sensing insulation layer ranges from 60 degrees to 90 degrees.

5. The display device of claim 4, wherein the side angle ranges from 60 degrees to 70 degrees, and a difference between the first refractive index and the second refractive index ranges from 0.25 to 0.35.

6. The display device of claim 4, wherein the separation distance increases as the side angle decreases.

7. The display device of claim 1, wherein the first refractive index ranges from 1.5 to 1.8.

8. The display device of claim 1, wherein the second refractive index ranges from 1.3 to 1.5.

9. The display device of claim 1, wherein the input sensing unit includes:
a first sensing insulation layer disposed on the display panel;
a first conductive layer disposed on the first sensing insulation layer and overlapping the non-emissive region;
a second sensing insulation layer disposed on the first sensing insulation layer and covering at least part of the first conductive layer; and
a second conductive layer disposed on the second sensing insulation layer and overlapping the non-emissive region, and
wherein the low refractive index layer covers the second conductive layer.

10. The display device of claim 1, wherein the separation distance increases as a thickness of the high refractive index pattern increases.

11. The display device of claim 1, wherein the separation distance increases as a difference between the first refractive index and the second refractive index increases.

12. The display device of claim 1, wherein the plurality of emissive regions include a first emissive region for emitting red light and a second emissive region for emitting green light,
wherein the high refractive index pattern is provided in plurality,
wherein the plurality of high refractive index patterns include a first high refractive index pattern covering the first emissive region in the plan view and a second high refractive index pattern covering the second emissive region in the plan view,
wherein one side surface of the first high refractive index pattern is spaced apart from one side surface of the first emissive region closest to the one side surface of the first high refractive index pattern by a first separation distance in the plan view,
wherein one side surface of the second high refractive index pattern is spaced apart from one side surface of the second emissive region closest to the one side surface of the second high refractive index pattern by a second separation distance in the plan view, and
wherein the second separation distance is different from the first separation distance.

13. The display device of claim 12, wherein the second separation distance is greater than the first separation distance.

14. The display device of claim 1, further comprising:
a polarization unit directly disposed on the low refractive index layer.

15. The display device of claim 1, wherein the high refractive index pattern has a thickness of 10 μm or more.

16. A display device comprising:
a display panel including a plurality of emissive regions and a non-emissive region adjacent to the plurality of emissive regions;
an input sensing unit disposed on the display panel, and including a sensing insulation layer disposed on the display panel and a conductive layer disposed on the sensing insulation layer, wherein the conductive layer overlaps the non-emissive region;
a light control layer disposed on the input sensing unit; and
a window disposed on the light control layer, and including a front surface and a curved surface curved from the front surface,
wherein the light control layer includes:
a low refractive index pattern disposed on the sensing insulation layer, covering the conductive layer, overlapping the non-emissive region, and having a first refractive index; and
a high refractive index layer covering the low refractive index pattern and overlapping the non-emissive region and the emissive regions, wherein the high refractive index layer has a second refractive index greater than the first refractive index, and
wherein a separation distance by which one side surface of the low refractive index pattern is spaced apart from one side surface of the emissive region closest to the one side surface of the low refractive index pattern ranges from 6 μm to 9 μm in the plan view.

17. The display device of claim 16, wherein the display panel includes:
a base layer;
a light emitting element disposed on the base layer and overlapping the emissive regions; and
a thin film encapsulation layer disposed on the light emitting element and sealing the light emitting element, and
wherein the thin film encapsulation layer has a thickness of 10 μm to 11 μm.

18. The display device of claim 16, wherein a side angle formed by a side surface of the low refractive index pattern with respect to an upper surface of the sensing insulation layer ranges from 90 degrees to 120 degrees.

19. The display device of claim 16, wherein the first refractive index ranges from 1.3 to 1.5.

20. The display device of claim 16, wherein the second refractive index ranges from 1.5 to 1.8.
